(19) United States
(12) Patent Application Publication
(10) Pub. No.: US 2025/0096210 A1
(43) Pub. Date: Mar. 20, 2025

(54) POWER MODULE WITH STACKED STRUCTURE

(71) Applicant: Monolithic Power Systems, Inc., Kirkland, WA (US)

(72) Inventors: Ting Ge, San Jose, CA (US); Daocheng Huang, Santa Clara, CA (US)

(21) Appl. No.: 18/661,267

(22) Filed: May 10, 2024

Related U.S. Application Data
(63) Continuation-in-part of application No. 18/469,800, filed on Sep. 19, 2023.

(51) Int. Cl. H01L 25/16; H01F 27/08; H01F 27/26; H01F 37/00; H01L 23/00; H01L 23/367; H01L 23/498; H02M 3/158

(52) U.S. Cl. CPC H01L 25/16; H01F 27/08; H01F 37/00; H01L 23/367; H01L 23/49811; H01L 23/49838; H01F 27/266; H01L 24/16; H01L 24/32; H01L 24/73; H01L 2224/16225; H01L 2224/32225; H01L 2224/73204; H02M 3/1586

(57) ABSTRACT

A power module has an inductor assembly and a device substrate. The inductor assembly comprises a magnetic core, a first winding and a second winding. Each of the first winding and the second winding has a first end and a second end exposed at the second surface of the inductor assembly. The device substrate has a first power device chip and a second power device chip at least partially embedded within the device substrate. The device substrate further has a first top heat layer at least partially covering the first power device chip and a second top heat layer at least partially covering the second power device chip. The first end of the first winding is electrically connected to the first top heat layer, and the first end of the second winding is electrically connected to the second top heat layer.

### CROSS-REFERENCE TO RELATED APPLICATIONS

The present application is a continuation-in-part of U.S. application Ser. No. 18/469,800 filed on Sep. 19, 2023, which is incorporated herein by reference in its entirety.

### BACKGROUND OF THE INVENTION

### 1. Field of the Invention

The present invention relates generally to electronic components, and more particularly but not exclusively to power modules.

### 2. Description of Related Art

Power converter, as known in the art, converts an input power to an output power for providing a load with required voltage and current. Multi-phase power converter comprising a plurality of paralleled power stages operating out of phase has lower output ripple voltage, better transient performance and lower ripple-current-rating requirements for input capacitors. They are widely used in high current and low voltage applications, such as server, microprocessor.

With the development of modern GPUs (Graphics Processing Units), and CPUs (Central Processing Units), increasingly high load current is required to achieve better processor performance. Besides, to improve integration density of the terminal products like CPUs and GPUs, the size of their power converters needs to be smaller. Higher current and smaller size put more challenges to the heat conduction of the power converters. Therefore, high-power density and high-efficiency power modules with excellent heat dissipation path are necessary for the processers.

### SUMMARY OF THE INVENTION

It is an object of the present invention to provide a power module with stacked inductors and power device chips.

Embodiments of the present invention are directed to a power module comprising: a device substrate having a first surface and a second surface opposite to the first surface of the device substrate, and an inductor assembly having a first surface and a second surface opposite to the first surface of the inductor assembly. The device substrate comprises a first power device chip, a second power device chip, a first top heat layer at least partially covering the first power device chip, and a second top heat layer at least partially covering the second power device chip. Each of the first top heat layer and the second top heat layer has a surface exposed at the first surface of the device substrate. The inductor assembly comprises a magnetic core, a first winding, a second winding, a first heat sink layer and a second heat sink layer. The first winding and the second winding are at least partially embedded within the magnetic core. Each of the first winding and the second winding has a first end and a second end exposed at the second surface of the inductor assembly. The first heat sink layer and the second heat sink layer wrap at least partial of the inductor assembly. The first heat sink layer and the first end of the first winding are electrically connected to the first top heat layer, and the second heat sink layer and the first end of the second winding are electrically connected to the second top heat layer.

Embodiments of the present invention are directed to a power module, comprising: an inductor assembly having a first surface and a second surface opposite to the first surface of the inductor assembly, and a device substrate having a first surface and a second surface opposite to the first surface of the device substrate. The inductor assembly comprises a magnetic core, a first winding and a second winding. The first winding and the second winding are at least partially embedded within the magnetic core. Each of the first winding and the second winding has a first end and a second end exposed at the second surface of the inductor assembly. The device substrate comprises a first power device chip, a second power device chip, a first top heat layer at least partially covering the first power device chip, a second top heat layer at least partially covering the second power device chip, a first connecting pillar and a second connecting pillar. The first power device chip and the second power device chip are at least embedded within the device substrate. Each of the first power device chip and the second power device chip has a first switch, a second switch and a switching pin electrically connected to a common node of the first switch and the second switch. The first connecting pillar is electrically connected to the switching pin of the first power device chip, and the second connecting pillar electrically connected to the switching pin of the second power device chip. The first end of the first winding is electrically connected to the first top heat layer and the first connecting pillar, and the first end of the second winding is electrically connected to the second top heat layer and the second connecting pillar.

Embodiments of the present invention are directed to a power module, comprising: an inductor assembly having a first surface and a second surface opposite to the first surface of the inductor assembly, and a device substrate having a first surface and a second surface opposite to the first surface of the device substrate. The inductor assembly comprises a magnetic core, a first winding and a second winding at least partially embedded within the magnetic core. Each of the first winding and the second winding has a first end and a second end exposed at the second surface of the inductor assembly. The device substrate comprises a first power device chip and a second power device chip at least partially embedded within the device substrate, a first top heat layer at least partially covering the first power device chip, and a second top heat layer at least partially covering the second power device chip. The first end of the first winding is electrically connected to the first top heat layer, and the first end of the second winding is electrically connected to the second top heat layer.

These and other features of the present invention will be readily apparent to persons of ordinary skill in the art upon reading the entirety of this disclosure, which includes the accompanying drawings and claims.

### BRIEF DESCRIPTION OF THE DRAWINGS

The present invention can be further understood with reference to following detailed description and appended drawings, wherein like elements are provided with like reference numerals. These drawings are only for illustration purpose, thus may only show part of the devices and are not necessarily drawn to scale.

FIG. 1 schematically shows a prior art multi-phase power converter 10 which comprises a controller 101, N power devices 103 and N inductors L for supplying power to a load 104.

FIG. 2 shows a power module 20 for a dual-phase power converter in accordance with an embodiment of the present invention.

FIG. 3 shows a disassembled and perspective view illustrating the power module 20 of FIG. 1.

FIG. 4 shows a cross sectional view illustrating the power module 20 taken along AA′ line of FIG. 1 in accordance with an embodiment of the present invention.

FIG. 5 shows a bottom view of the inductor assembly 203 in accordance with an embodiment of the present invention.

FIG. 6 shows a top view of the device substrate 202 in accordance with an embodiment of the present invention.

FIG. 7 shows a bottom view of the device substrate 202 in accordance with an embodiment of the present invention.

FIG. 8 shows a bottom view of the bottom substrate 201 in accordance with an embodiment of the present invention.

FIG. 9 is a side view illustrating a system 90 employing the power module 20 in accordance with an embodiment of the present invention.

FIG. 10 shows a power module 30 for a dual-phase power converter in accordance with another embodiment of the present invention.

FIG. 11 shows a disassembled and perspective view illustrating the power module 30 of FIG. 10.

FIG. 12 shows a bottom view of the inductor assembly 303 in accordance with an embodiment of the present invention.

FIG. 13 shows a top view of the device substrate 302 in accordance with an embodiment of the present invention.

FIG. 14 shows a bottom view of the device substrate 302 in accordance with an embodiment of the present invention.

FIG. 15 shows a cross-sectional view illustrating the power module 30 taken along CC′ line of FIG. 10 in accordance with an embodiment of the present invention.

FIG. 16 shows a cross-sectional view illustrating the power module 30 taken along DD′ line of FIG. 10 in accordance with an embodiment of the present invention.

FIG. 17 shows a power module 40 for a dual-phase power converter in accordance with another embodiment of the present invention.

FIG. 18 shows a disassembled and perspective view illustrating the power module 40 of FIG. 17.

FIG. 19 shows a bottom view of the inductor assembly 403 in accordance with an embodiment of the present invention.

FIG. 20 shows a bottom view of the device substrate 402 in accordance with an embodiment of the present invention.

FIG. 21 shows a cross-sectional view illustrating the power module 40 taken along EE′ line of FIG. 17 in accordance with an embodiment of the present invention.

FIG. 22 shows a power module 50 for a dual-phase power converter in accordance with another embodiment of the present invention.

FIG. 23 shows a disassembled and perspective view illustrating the power module 50 of FIG. 22.

FIG. 24 shows a bottom view of the inductor assembly 503 in accordance with an embodiment of the present invention.

FIG. 25 shows a bottom view of the device substrate 502 in accordance with an embodiment of the present invention.

FIG. 26 shows a cross-sectional view illustrating the power module 50 taken along FF′ line of FIG. 22 in accordance with an embodiment of the present invention.

FIG. 27 shows a cross-sectional view illustrating the power module 30 taken along GG′ line of FIG. 22 in accordance with an embodiment of the present invention.

### DETAILED DESCRIPTION

In the present disclosure, numerous specific details are provided, such as examples of electrical circuits and components, to provide a thorough understanding of embodiments of the invention. Persons of ordinary skill in the art will recognize, however, that the invention can be practiced without one or more of the specific details. It is noted that, for purposes of illustrative clarity, certain elements in the drawings may not be drawn to scale. In other instances, well-known details are not shown or described to avoid obscuring aspects of the invention.

Throughout the specification and claims, the terms “left”, “right”, “in”, “out”, “front”, “back”, “up”, “down”, “top”, “atop”, “bottom”, “on”, “over”, “under”, “above”, “below”, “vertical” and the like, if any, are used for descriptive purposes and not necessarily for describing permanent relative positions. It is to be understood that the terms so used are interchangeable under appropriate circumstances such that embodiments of the technology described herein are, for example, capable of operation in other orientations than those illustrated or otherwise described herein. The phrases “in one embodiment”, “in some embodiments”, “in one implementation”, and “in some implementations” as used includes both combinations and sub-combinations of various features described herein as well as variations and modifications thereof. These phrases used herein does not necessarily refer to the same embodiment, although it may. Those skilled in the art should understand that the meanings of the terms identified above do not necessarily limit the terms, but merely provide illustrative examples for the terms. It is noted that when an element is “connected to” or “coupled to” the other element, it means that the element is directly connected to or coupled to the other element, or indirectly connected to or coupled to the other element via another element. Particular features, structures or characteristics may be included in an integrated circuit, an electronic circuit, a combinational logic circuit, or other suitable components that provide the described functionality. In addition, it is appreciated that the figures provided herewith are for explanation purposes to persons ordinarily skilled in the art and that the drawings are not necessarily drawn to scale.

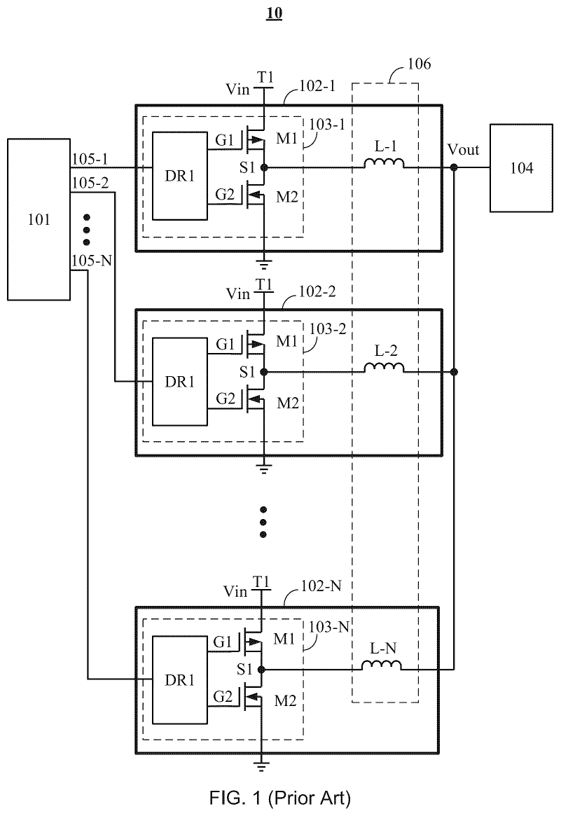

FIG. 1 schematically shows a prior art multi-phase power converter 10 which comprises a controller 101, N power blocks 103-1˜103-N and N inductors L-1˜L-N for supplying power to a load 104, wherein N is an integer, and N≥1. Each power block 103 and one inductor L represent one power stage, i.e., one phase 102 of the power converter 10, as shown in FIG. 1. Each power block 103 includes switches M1, M2 and a driver DR1 for providing driving signals G1 and G2 to drive the switches M1 and M2 respectively. The controller 101 provides N phase control signals 105-1˜105-N respectively to N power blocks 103-1˜103-N to control the N phases 102-1˜102-N working out of phase, i.e., each one of the inductors L-1˜L-N sequentially absorb power from the input source and sequentially deliver power to the load 104. It should be noticed that the outputs of all phases as shown in FIG. 1 are connected to work as a multi-phase converter. However, each phase output may be separated to work as multiple independent converters which could have different output voltage levels for different load demands.

The power stage 102 with Buck topology is shown in FIG. 1 for example. Persons of ordinary skill in the art should appreciate that power stages with other topologies, like Boost topology, Buck-Boost topology could also be adopted in a multi-phase power converter.

The inductors L-1˜L-N could be implemented by one or a few coupled inductors or could be implemented by N single inductors.

When N=2, the multi-phase power converter 10 is used as a dual-phase power converter or two separate single-phase converters. For the ease of description, dual-phase power module for a dual-phase power converter is discussed as an example to illustrate the present invention.

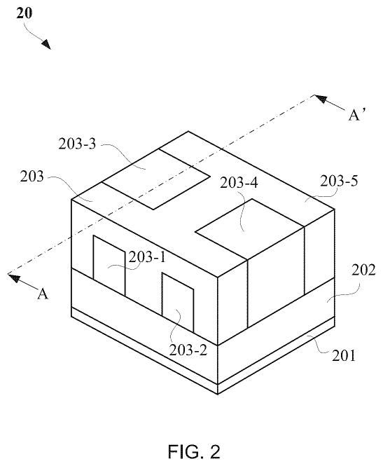

FIG. 2 shows a power module 20 for a dual-phase power converter in accordance with an embodiment of the present invention. The power module 20 may serve as the power stage 102 of FIG. 1, with N=2. The power module 20 includes a bottom substrate 201, a device substrate 202 and an inductor assembly 203. The bottom substrate 201 is arranged at the bottom of the power module 20. The device substrate 202 is arranged on the bottom substrate 201. The inductor assembly 203 is arranged on the device substrate 202. Power device chips integrating the components of the power blocks 103 shown in FIG. 1 is embedded within the device substrate 202. The inductors L are integrated in the inductor assembly 203.

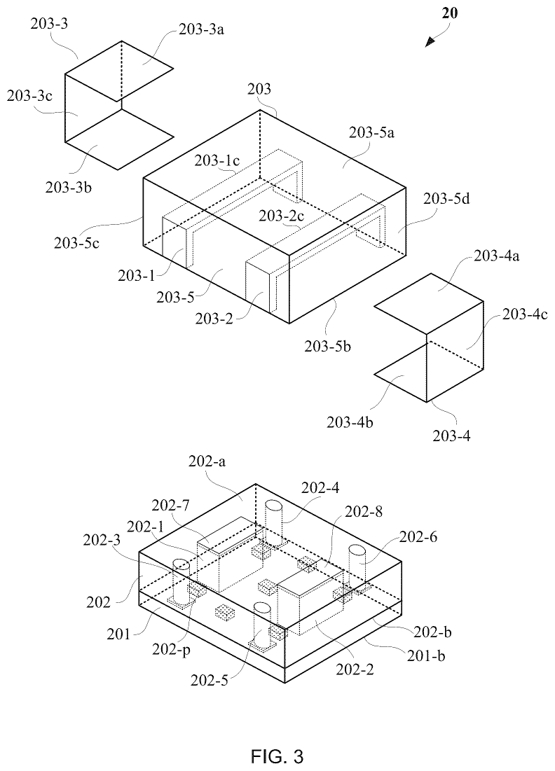

FIG. 3 shows a disassembled and perspective view illustrating the power module 20 of FIG. 2. As shown in FIG. 3, the device substrate 202 includes a first power device chip 202-1, a second power device chip 202-2, a first pair of connecting pillars 202-3 and 202-4, a second pair of connecting pillars 202-5 and 202-6, and a plurality of discrete components 202-p embedded within the device substrate 202. Each one of the first power device chip 202-1 and the second power device chip 202-2 integrates one power block 103 in FIG. 1, which includes the switches M1, M2, the driver DR1, and further integrates some auxiliary circuits not shown in FIG. 1. The first pair of the connecting pillars includes a first connecting pillar 202-3 and a second connecting pillar 202-4 arranged at opposite sides of the first power device chip 202-1. The second pair of the connecting pillars includes a third connecting pillar 202-5 and a fourth connecting pillar 202-6 arranged at opposite sides of the second power device chip 202-2. Each one of the connecting pillars has a first end connecting out of the device substrate 202, and connected to the corresponding winding of the inductor assembly 203, and a second end connected to the bottom substrate 201. The connecting pillars shown in the example of FIG. 3 are cylinders. It should be appreciated that any shape of the connecting pillars is applicable to the present invention. The discrete components 202-p include resistors and capacitors of the power converter 10, like the input capacitors at the input terminal T1 of the power converter 10 for receiving the input voltage Vin to provide pulse current, the filter capacitors and resistors for the drivers DR1 and internal logic circuits power supplies (not shown in FIG. 1), etc.

In the example of FIG. 3, the inductor assembly 203 includes a magnetic core 203-5, a first winding 203-1 and a second winding 203-2 passing through the magnetic core 203-5. The first winding 203-1 and the magnetic core 203-5 form a first inductor L-1 as shown in FIG. 1. The second winding 203-2 and the magnetic core 203-5 form a second inductor L-2 as shown in FIG. 1. Furthermore, the inductor assembly 203 includes a first heat sink layer 203-3 and a second heat sink layer 203-4, each of which has a “C” shape, and partially wraps the magnetic core 203-5. As can be seen from FIG. 3, the first heat sink layer 203-3 has a first portion 203-3a partially covering a first surface 203-5a of the magnetic core 203-5, a second portion 203-3b partially covering a second surface 203-5b of the magnetic core 203-5, and a third portion 203-3c connecting the first portion 203-3a and the second portion 203-3b, and partially covering a third surface 203-5c of the magnetic core 203-5, wherein the first surface 203-5a and the second surface 203-5b are opposite, and the third surface 203-5c is vertical to the first surface 203-5a and the second surface 203-5b. The second heat sink layer 203-4 has a first portion 203-4a partially covering the first surface 203-5a, a second portion 203-4b partially covering the second surface 203-5b, and a third portion 203-4c connecting the first portion 203-4a and the second portion 203-4b, and covering a fourth surface 203-5d of the magnetic core 203-5, wherein the fourth surface 203-5d is opposite to the third surface 203-5c, and is vertical to the first surface 203-5a and the second surface 203-5b of the magnetic core 203-5. The surfaces of the magnetic core 203-5 are also referred as surfaces of the inductor module 203. It should be appreciated that the first heat sink layer 203-3 and the second heat sink layer 203-4 are configured for transferring heat from the power device chips to the environment or external components. The shape of the first heat sink layer 203-3 and the second heat sink layer 203-4 may be varying in different applications, e.g., the first heat sink layer 203-3 may have a “L” shape with the second portion 203-3b and the third portion 203-3c, and similarly, the second heat sink layer 203-4 may have a “L” shape with the second portion 203-4b and the third portion 203-4c.

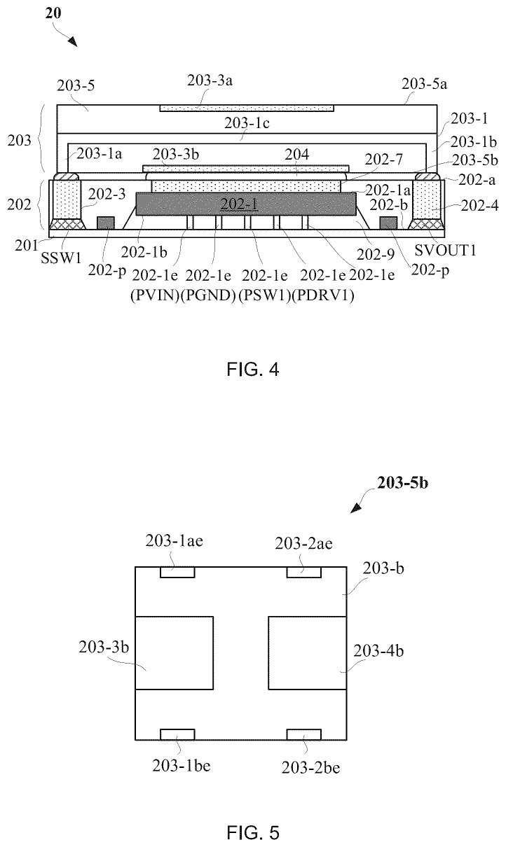

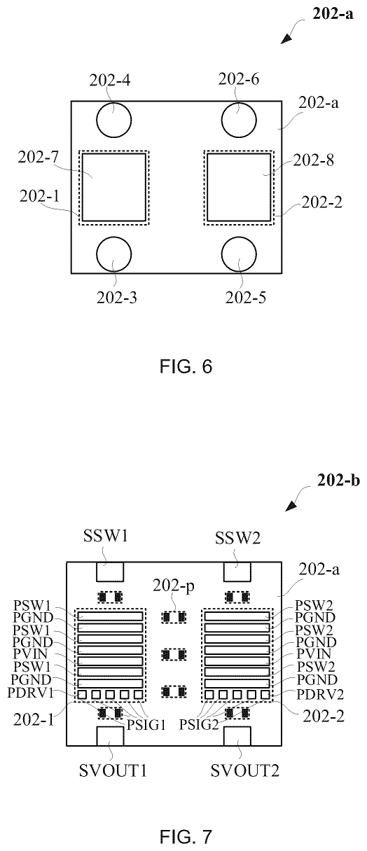

FIG. 4 shows a cross-sectional view illustrating the power module 20 taken along AA′ line of FIG. 2 in accordance with an embodiment of the present invention. FIG. 5 shows a bottom view of the inductor assembly 203, i.e., the second surface 203-5b of the inductor assembly 203, in accordance with an embodiment of the present invention. FIG. 6 shows a top view of the device substrate 202, i.e., the first surface 202-a of the device substrate 202, in accordance with an embodiment of the present invention. FIG. 7 shows a bottom view of the device substrate 202, i.e., the second surface 202-b of the device substrate 202, in accordance with an embodiment of the present invention. The structure of the power module 20 will be illustrated with reference to FIGS. 3˜7.

As shown in FIG. 4, the first power device chip 202-1 has a first surface 202-1a and a second surface 202-1b. The first surface 202-1a is covered by a top heat layer 202-7 as shown in FIGS. 4 and 6, and the second surface 202-1b has a plurality of pins 202-1e (including pins PVIN, PGND, PSW1, PDRV1, and etc.) exposed on the second surface 202-b of the device substrate 202 as shown in FIGS. 4 and 7, and connected to the bottom substrate 201. Similarly, The first surface 202-2a of the second power device chip 202-2 is covered by a top heat layer 202-8 as shown in FIG. 6, and the second surface 202-2b of the second power device chip 202-2 has a plurality of pins 202-2e (including pins PVIN, PGND, PSW2, PDRV2, and etc.) exposed on the second surface 202-b of the device substrate 202 as shown in FIG. 7, and connected to the bottom substrate 201. It should be appreciated that the pins shown in FIGS. 4 and 7 are for illustration purpose. More pins may be configured in a real application. Furthermore, the pin shape, the pin size and the pin distribution would be varying in different applications. The top heat layer 202-7 and the top heat layer 202-8 are heat disposal layers, which are made of copper in one embodiment, and are made of other material in other embodiments. Persons of ordinary skill in the art should appreciate that any suitable layer configured to transfer heat from the power device chip is applicable as the top heat layer. In one embodiment, the first portion 203-3a of the first heat sink layer 203-3 and the first portion 203-4a of the second heat sink layer 203-4 are extending to each other and merged as one piece. In one embodiment, the second portion 203-3b of the first heat sink layer 203-3 and the second portion 203-4b of the second heat sink layer 203-4 are extending to each other and merged as one piece. In one embodiment, the first portion 203-3a of the first heat sink layer 203-3 and the first portion 203-4a of the second heat sink layer 203-4 are removed, and a heat radiator may remove heat from the first power device chip 202-1 and the second power device chip 202-2 via the third portion 203-3c of the first heat sink layer 203-3 and the third portion 203-4c of the second heat sink layer 203-4. Similarly, the top heat layer 202-7 and the top heat layer 202-8 could be merged as a whole piece.

As mentioned before, the first power device chip 202-1 integrates the switches M1, M2, the driver DR1 shown in FIG. 1, and other accessory circuits not shown in FIG. 1. The plurality of pins 202-1e of the first power device chip 202-1 includes at least an input pin PVIN, a switching pin PSW1, a ground pin PGND, and a driving pin PDRV1 as shown in FIG. 7. The first switch M1 has a first terminal coupled to the input pin PVIN (corresponding to the input terminal T1 in FIG. 1) to receive the input voltage Vin (shown in FIG. 1), a second terminal connected to the switching pin PSW1 (corresponding to the switching terminal S1 in FIG. 1), and a control terminal configured to receive a first driving signal G1. The second switch M2 has a first terminal connected to the switching pin PSW1, a second terminal connected to the ground pin PGND, and a control terminal configured to receive a second driving signal G2. The driver DR1 is coupled to the driving pin PDRV1 to receive a phase control signal 105, and to provide the first driving signal G1 and the second driving signal G2 based on the phase control signal 105. The plurality of pins of the power device chips 202-1 and 202-2 are electrically connected to external circuits/devices/components via the bottom substrate 201. The bottom substrate 201 may be attached to a mainboard where the load (CPU, GPU, etc.) located, and there may be circuits/devices/components on the mainboard providing the input voltage Vin, the phase control signal 105, and a ground reference GND that provides a common ground for the first power device chip 202-1 and the second power device chip 202-2 via the ground pins PGND.

It should be appreciated that the second power device chip 202-2 has the same structure as the first power device chip 202-1, and is not discussed for the brevity of description.

The first winding 203-1 and the second winding 203-2 are embedded in the magnetic core 203-5 and have an upside-down “U” shape, and are parallel to each other. In the example shown in FIG. 4, the first winding 203-1 has a first portion 203-1a and a second portion 203-1b having ends 203-1ae and 203-1be connected out of the second surface 203-5b of the magnetic core 203-5, and has a middle portion 203-1c parallel to the first surface 203-5a of the magnetic core 203-5 and connecting the first portion 203-1a and the second portion 203-1b. The end 203-1ae of the first portion 203-1a of the first winding 203-1 connects out of the second surface 203-5b of the magnetic core 203-5 as shown in FIG. 5, and is electrically connected to the first connecting pillar 202-3 embedded within the device substrate 202 by soldering or other connecting means as shown in FIG. 4. The end 203-1be of the second portion 203-1b of the first winding 203-1 connects out of the second surface 203-5b of the magnetic core 203-5 as shown in FIG. 5, and is electrically connected to the second connecting pillar 202-4 embedded within the device substrate 202 by soldering or other connecting means as shown in FIG. 4. It should be appreciated that the second winding 203-2 has the similar structure with the first winding 203-1 as shown in FIG. 3, and has two ends 203-2ae and 203-2be electrically connected to third connecting pillar 202-5 and the fourth connecting pillar 202-6 respectively.

The second portion 203-3b of the first heat sink layer 203-3 partially covers the second surface 203-5b of the magnetic core 203-5 as shown in FIG. 5, and is attached to the top heat layer 202-7 directly or via a heat conductive contact 204 as shown in the example of FIG. 4. Similarly, the second portion 203-4b of the second heat sink layer 203-4 partially covers the second surface 203-5b of the magnetic core 203-5 as shown in FIG. 5, and is attached to a top heat layer on top of the second power device chip 202-2 directly or via a heat conductive contact. In one embodiment, the heat sink layers 203-3 and 203-4 are made of copper, and dissipate heat from the top heat layers on top of the power device chips 202-1 and 202-2. Consequently, the heat of the power device chips 202-1 and 202-2 are dissipated via the top heat layers 202-7 and 202-8 and the heat sink layer 203-3 and 203-4, respectively. The heat sinks 203-3 and 203-4 are attached to the magnetic core 203-5 by either thermal glue, thermal paste, or direct contact.

The first connecting pillar 202-3 has one end connecting out of the first surface 202-a of the device substrate 202 as shown in FIG. 6, and connected to the end of the first portion 203-1a of the first winding 203-1 as shown in FIG. 4, and has the other end connected to the bottom substrate 201 via a first switching terminal SSW1. Furthermore, the end of the first portion 203-1a of the first winding 203-1, and the first connecting pillar 202-3, are electrically connected to the switching pin PSW1 of the first power device chip 202-1 via conductive traces inside the bottom substrate 201. Consequently, the heat of the first power device chip 202-1 is further dissipated through the first connecting pillar 202-3 and the first winding 203-1. The second connecting pillar 202-4 has one end connecting out of the first surface 202-a of the device substrate 202 and connected to the end of the second portion 203-1b of the first winding 203-1, and has the other end connected to the bottom substrate 201 via a first output voltage terminal SVOUT1. The third connecting pillar 202-5 has one end connecting out of the first surface 202-a of the device substrate 202 as shown in FIG. 6, and connected to the end 203-2ae of the first portion 203-2a of the second winding 203-2 shown in FIG. 5, and has the other end connected to the bottom substrate 201 via a second switching terminal SSW2. The end 203-2ae of the first portion 203-2a of the second winding 203-2, and the third connecting pillar 202-5, are electrically connected to the switching pin PSW2 of the second power device chip 202-2 via conductive traces inside the bottom substrate 201. Consequently, the heat of the second power device chip 202-2 is further dissipated through the third connecting pillar 202-5 and the second winding 203-2. The fourth connecting pillar 202-6 has one end connecting out of the first surface 202-a of the device substrate 202 and connected to the end 203-2be of the second portion 203-2b of the second winding 203-2, and has the other end connected to the bottom substrate 201 via a second output voltage terminal SVOUT2. In some embodiments of the present invention, the connecting pillars 202-3˜202-6 are soldered to the bottom substrate 201, and the first switching terminal SSW1, the first output voltage terminal SVOUT1, the second switching terminal SSW2 and the second output voltage terminal SVOUT2 are solder pastes at the ends of the connecting pillars 202-3˜202-6. It should be appreciated that the connecting pillars 202-3˜202-6 may be connected to the bottom substrate 201 directly, or by other connecting means known in the art, e.g., the connecting pillars 202-3˜202-6 may be protruded out of the bottom surface 202-b of the device substrate 202, and are inserted to grooves of the bottom substrate 201.

As shown in FIG. 7, the first power device chip 202-1 has signal pins PSIG1 which may be configured to transmit temperature monitoring signal, current monitoring signal, and other necessary signals for communicating between the first power device chip 202-1 and external circuits. The second power device chip 202-2 has signal pins PSIG2 which may be configured to transmit temperature monitoring signal, current monitoring signal, and other necessary signals for communicating between the second power device chip 202-2 and external circuits. In FIG. 7, the driving pin PDRV1 is illustrated as an example of signal pins PSIG1, and the driving pin PDRV2 is illustrated as an example of signal pins PSIG2. Other signal pins, like the pins for transmitting the temperature monitoring signal, the current monitoring signal, etc., are not specifically labeled for brevity. The discrete components 202-p together with the power device chips 202-1 and 202-2 which are molded within the device substrate 202 have connecting terminals on the second surface of the device substrate 202. As shown in the embodiment of FIG. 7, each one of the discrete components 202-p, i.e., the capacitors and the resistors, has two pins or pads exposed on the second surface 202-b of device substrate 202, and connected to the bottom substrate 201, wherein the discrete components 202-p are electrically connected to the power device chips 202-1, 202-2, and external components/circuits via the bottom substrate 201. Persons of ordinary skill in the art should know that the pins shown in FIG. 7 are for illustrating, which should not be limiting the present invention. The pin distribution on the second surface of the device substrate 202 is determined by the requirement of the application specs, and is varying in different applications.

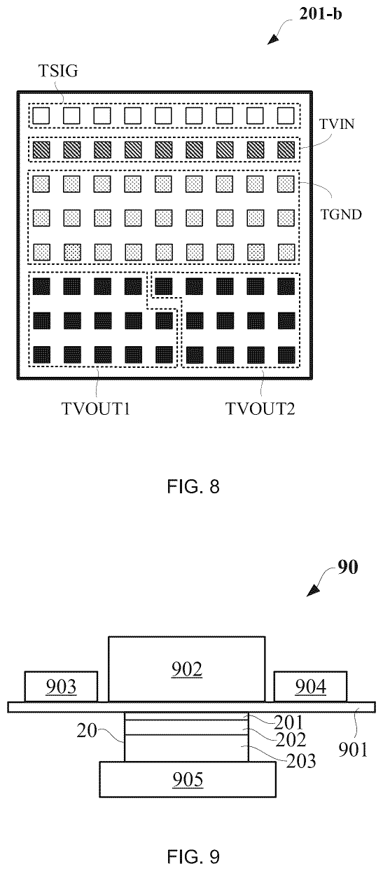

FIG. 8 shows a bottom view of the bottom substrate 201, i.e., the second surface 201-b of the bottom substrate 201, in accordance with an embodiment of the present invention. The second surface 201-b of the bottom substrate 201 includes a signal pad area TSIG, an input pad area TVIN, a ground pad area TGND, a first output voltage pad area TVOUT1 and a second output voltage pad area TVOUT2. Each one of the pad areas includes a plurality of pads. The pads on the second surface 201-b of the bottom substrate 201 connect through to the first surface 201-a of the bottom substrate 201 using, e.g., vias and conductive traces inside the bottom substrate 201. The plurality of pads of the signal pad area TSIG are electrically connected to the signal pins PSIG1 of the first power device chip 202-1 and the signal pins PSIG2 of the second power device chip 202-2 respectively, like the driving pins PDRV1, PDRV2, temperature monitoring pins, etc. The plurality of pads of the input pad area TVIN are electrically connected to the input pins PVIN of the first power device chip 202-1 and the second power device chip 202-2. The plurality of pads of the ground pad area TGND are electrically connected to the ground pins PGND of the first power device chip 202-1 and the second power device chip 202-2. The plurality of pads of the first output voltage pad area TVOUT1 are electrically connected to the end of the second portion 203-1b of the first winding 203-1 via the second connecting pillar 202-4. The plurality of pads of the second output voltage pad area TVOUT2 are electrically connected to the end of the second portion 203-2b of the second winding 203-2 via the fourth connecting pillar 202-6. In one embodiment, the pads of the first output voltage pad area TVOUT1 and the pads of the second output voltage pad area TVOUT2 are electrically disconnected, which makes the power module 20 work as two independent converters. In some embodiments, the pads of the first output voltage pad area TVOUT1 and the pads of the second output voltage pad area TVOUT2 are electrically connected by external conductive traces or traces inside the bottom substrate, which makes the power module 20 work as a dual-phase power converter.

In the present invention, by stacking the bottom substrate 201, the device substrate 202 and the inductor assembly 203 vertically, the power density is increased. The first portions and the second portions of the first winding and the second winding are exposed to the side surfaces of the magnetic core as shown in the embodiments of the present invention. It should be appreciated that the first portions and the second portions of the first winding and the second winding could be totally embedded inside the magnetic core, thereby switching noise is shielded by the magnetic core 205 and the device substrate 202 of the power module 20, thus better noise immunity is provided compared to the prior art power modules.

In the present invention, the power device chips embedded within the device substrate dissipate heat from the top, i.e., through the top heat layers, and meanwhile from the bottom, i.e., through the pins attached to the bottom substrate, and then further through the windings and magnetic core of the inductor assembly, which makes the heat dissipation performance excellent.

In one embodiment, the device substrate 202 is formed by firstly attaching the power device chips 202-1 and 202-2, the discrete components 202-p, and the connecting pillars 202-3˜202-6 to the bottom substrate 201, and secondly molding all the aforementioned components together. The power module 20 could be produced by stacking the inductor module 203 on top (first surface 202-a) of the device substrate 202, which highly eases the manufacturability and improves the robustness.

It should be appreciated that the device substrate 202 could also be implemented by other means, e.g., by PCB (Printed Circuit Board) process. Specifically, the power device chips 202-1 and 202-2, the discrete components 202-p, and the connecting pillars 202-3˜202-6 could be integrated in a PCB or be embedded by several PCB layers.

In one embodiment, the bottom substrate 201 is implemented by a PCB layer.

FIG. 9 is a side view illustrating a system 90 employing the power module 20 in accordance with an embodiment of the present invention. The system 90 includes a mainboard 901, a load 902, external components 903, 904, the power module 20, and a heat radiator 905. In the embodiment of FIG. 9, the load 902 and the power module 20 are attached to the opposite surfaces of the mainboard 901, which shorts the power delivery path, and improves the power efficiency. The load 902 may be a CPU, a GPU, or any other microprocessors. The power module 20 is attached to the mainboard 901 by the bottom substrate 201. The top of the power module 20 is covered by the heat radiator 905 for heat dissipation. The external components 903 and 904 may be the devices providing power, i.e., the input voltage Vin, or providing the phase control signals 105, to the power module 20. In other embodiments, the power module 20 and the load 902 may be placed on the same surface of the mainboard 901.

The power module for the dual-phase power converter is described for illustrating the present invention. It should be appreciated that the power module in the present invention could be scaled in by including a single power device chip and a single inductor to implement a single-phase power converter, or be scaled out by including more power device chips and inductors to implement multiple power converters or a multi-phase power converter.

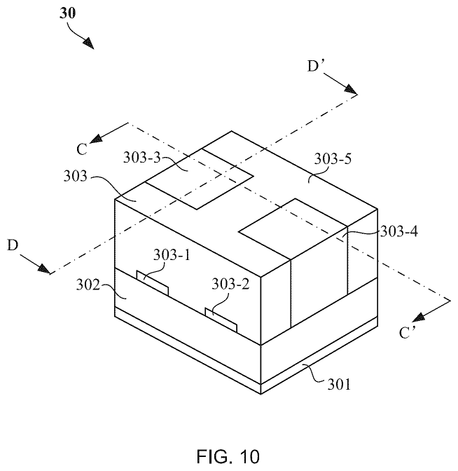

FIG. 10 shows a power module 30 for a dual-phase power converter in accordance with another embodiment of the present invention. The power module 30 may serve as the power stage 102 of FIG. 1, with N=2. The power module 30 includes a bottom substrate 301, a device substrate 302 and an inductor assembly 303. As shown in FIG. 10, the power module 30 has a stacked structure, i.e., the bottom substrate 301 is arranged at the bottom of the power module 30, having a first surface facing the device substrate 302 and a second surface opposite to the first surface for external connection, the device substrate 302 is arranged on the bottom substrate 301, and the inductor assembly 303 is arranged on the device substrate 302. The inductor assembly 303 comprises a first winding 303-1, a second winding 303-2 and a magnetic core 303-5, thus the inductors L (e.g., L-1 and L-2) are integrated in the inductor assembly 303. In the example of FIG. 10, the inductor assembly 303 further comprises heat sink layers 303-3 and 303-4.

In one embodiment, the second surface of the bottom substrate 301 of the power module 30 comprises a first output voltage pad area and a second output voltage pad area, an input pad area, a ground pad area and a signal pad area, wherein structure and connection of the pad areas on the second surface of the bottom substrate 301 are same as the pad areas on the second surface 201-b of the bottom surface 201 described previously in FIG. 8, and is not discussed for the brevity of description.

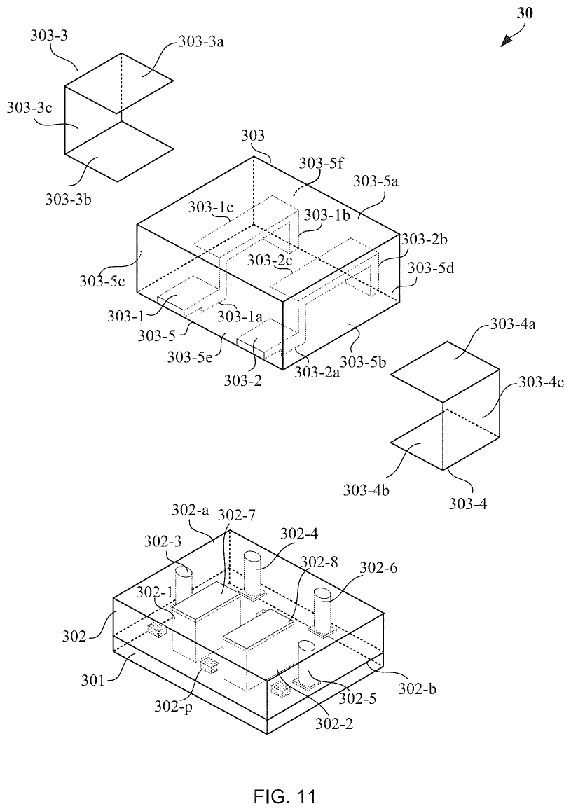

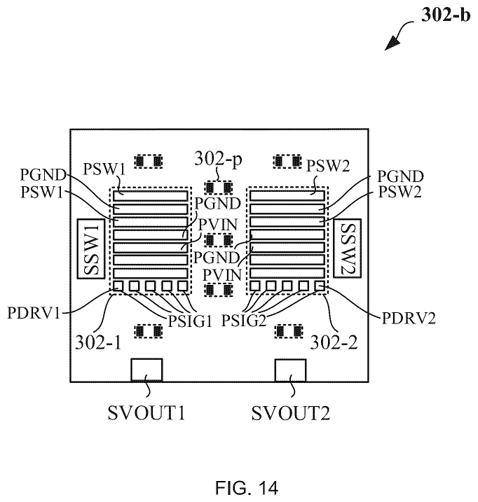

FIG. 11 shows a disassembled and perspective view illustrating the power module 30 of FIG. 10. As shown in FIG. 11, the device substrate 302 includes a first power device chip 302-1, a second power device chip 302-2, connecting pillars 302-3, 302-4, 302-5 and 302-6, and a plurality of discrete components 302-p, wherein all these components of the device substrate 302 are at least partially embedded within the device substrate 302. Each one of the first power device chip 302-1 and the second power device chip 302-2 integrates one power block 103 in FIG. 1, which includes the switches M1, M2, the driver DR1, and further integrates some auxiliary circuits not shown in FIG. 1. As shown in FIG. 11, the device substrate 302 has a first surface 302-a and a second surface 302-b opposite to the first surface 302-a. The first power device chip 302-1 is at least partially covered by a top heat layer 302-7, and the second power device chip 302-2 is at least partially covered by a top heat layer 302-8. Each of the top heat layers 302-7 and 302-8 has a surface exposed at the first surface 302-a of the device substrate 302. In the example of FIG. 11, a switching pin of the first power device chip 302-1 is electrically coupled to the top heat layer 302-7, e.g., via conductive traces in the bottom substrate 301, the connecting pillar 302-3 and the heat sink layer 303-3, and similarly, a switching pin of the second power device chip 302-2 is electrically coupled to the top heat layer 302-8, e.g., via conductive traces in the bottom substrate, the connecting pillar 302-5 and the heat sink layer 303-4, which will be further illustrated beginning with FIG. 14. Each of the connecting pillars 302-3, 302-4, 302-5, and 302-6 has a first end exposed at the first surface 302-a of the device substrate 302 to connect with the inductor assembly 303, and has a second end exposed at the second surface 302-b of the device substrate 302 to connect with the bottom substrate 301. The connecting pillars shown in the example of FIG. 11 are cylinders, and it should be appreciated that any shape of the connecting pillars is applicable to the present invention. The discrete components 302-p include resistors and capacitors of the power converter 10, like the input capacitors at the input terminal T1 of the power converter 10 for receiving the input voltage Vin to provide pulse current, the filter capacitors and resistors for the drivers DR1 and internal logic circuits power supplies (not shown in FIG. 1), etc.

In the example of FIG. 11, the first winding 303-1 and the second winding 303-2 pass through the magnetic core 303-5. The first winding 303-1 and the magnetic core 303-5 form the first inductor L-1 as shown in FIG. 1. The second winding 303-2 and the magnetic core 303-5 form the second inductor L-2 as shown in FIG. 1. In one embodiment, the first winding 303-1 and the second winding 303-2 are made of copper. Furthermore, each of the heat sink layers 303-3 and 303-4 has a “C” shape and wraps at least partial of the magnetic core 303-5. As can be seen from FIG. 11, the heat sink layer 303-3 has a portion 303-3a covering at least partial of a first surface 303-5a of the magnetic core 303-5, a portion 303-3b covering at least partial of a second surface 303-5b of the magnetic core 303-5, and a portion 303-3c connecting the portions 303-3a and 303-3b and covering at least partial of a third surface 303-5c of the magnetic core 303-5. The first surface 303-5a and the second surface 303-5b are opposite, and the third surface 303-5c is vertical to the first surface 303-5a and the second surface 303-5b. The heat sink layer 303-4 has a portion 303-4a covering at least partial of the first surface 303-5a, a portion 303-4b covering at least partial of the second surface 303-5b, and a portion 303-4c connecting the portions 303-4a and 303-4b, and covering at least partial of a fourth surface 303-5d of the magnetic core 303-5, wherein the fourth surface 303-5d is opposite to the third surface 303-5c, and is vertical to the first surface 303-5a and the second surface 303-5b of the magnetic core 303-5. As shown in FIG. 11, the magnetic core 303-5 further has a fifth surface 303-5e and a sixth surface 303-5f which are opposite to each other, and are vertical to the first surface 303-5a and the second surface 303-5b of the magnetic core 303-5. The surfaces of the magnetic core 303-5 are also referred as surfaces of the inductor assembly 303. The shapes of the heat sink layers 303-3 and 303-4 may be varying in different applications, e.g., the heat sink layer 303-3 may have a “L” shape with the portion 303-3b and the portion 303-3c, and similarly, the heat sink layer 303-4 may have a “L” shape with the portion 303-4b and the portion 303-4c. In one embodiment, the heat sink layers 303-3 and 303-4 are made of copper.

In the example of FIG. 11, the first winding 303-1 and the second winding 303-2 are at least partially embedded within the magnetic core 303-5, e.g., each of the first winding 303-1 and the second winding 303-2 may have at least a part exposed at one or more surfaces of the magnetic core 303-5. In the example shown in FIG. 11, the first winding 303-1 has a first portion 303-1a, a second portion 303-1b, and a third portion 303-1c connecting the first portion 303-1a and the second portion 303-1b. Similarly, the second winding 303-2 has a first portion 303-2a, a second portion 303-2b, and a third portion 303-2c connecting the first portion 303-2a and the second portion 303-2b. The third portion 303-1c of the first winding 303-1 and the third portion 303-2c of the second winding 303-2 are parallel to each other, and each has a top surface which is parallel to the first surface 303-5a of the magnetic core 303-5. Each of the first portion and the second portion of the first winding 303-1 has a part exposed at the second surface 303-5b of the magnetic core 303-5, and each of the first portion and the second portion of the second winding 303-1 has a part exposed at the second surface 303-5b of the magnetic core 303-5. In one embodiment, each of the first portions of the first winding 303-1 and 303-2 further has a part exposed at the fifth surface 303-5e, and each of the second portions of the first winding 303-1 and 303-2 further has a part exposed at the sixth surface 303-5e.

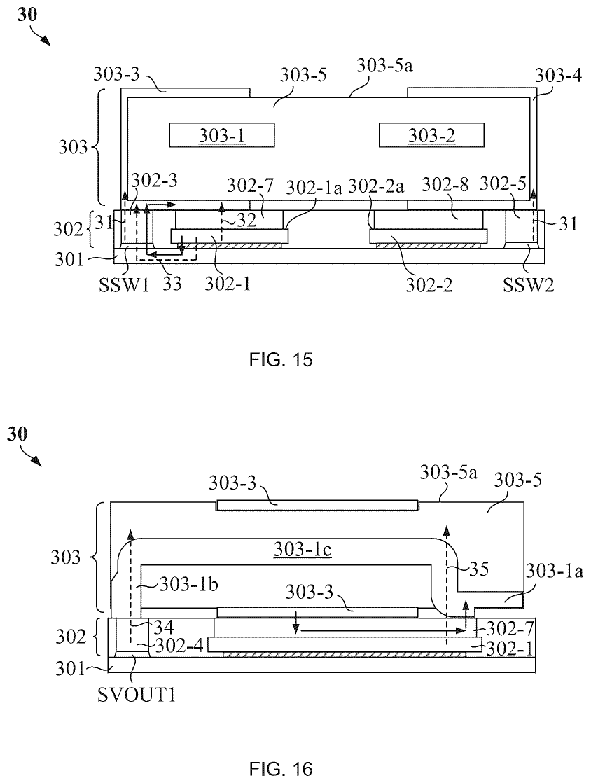

When the bottom substrate 301, the device substrate 302 and the inductor assembly 303 are assembled together, the second surface 302-b of the device substrate 302 faces the first surface of the bottom substrate 301, and the second surface 303-5b of the inductor assembly 301 faces the first surface 302-a of the device substrate 302. The first portion 303-1a of the first winding 303-1 is electrically connected to the top heat layer 302-7, and the first portion 303-2a of the second winding 303-2 is electrically connected to the top heat layer 302-8. The second portion 303-1b of the first winding 303-1 is electrically connected to the connecting pillar 302-4, and the second portion 303-2b of the second winding 303-2 is electrically connected to the connecting pillar 302-6. The second portion 303-1b of the first winding 303-1 and the second portion 303-2b of the second winding 303-2 are electrically connected to the first output voltage pad area and the second output voltage pad area respectively via the device substrate and the bottom substrate. The portion 303-3b of the heat sink layer 303-3 is electrically connected to the connecting pillar 302-3 and the top heat layer 302-7, and the portion 303-4b of the heat sink layer 303-4 is electrically connected to the connecting pillar 302-5 and the top heat layer 302-8. In one embodiment, the portion 303-3b of the heat sink layer 303-3 is physically attached to the first end of the connecting pillar 302-3 by soldering or via a conductive adhesive, and the portion 303-4b of the heat sink layer 303-4 is physically attached to the first end of the connecting pillar 302-5 by soldering or via a conductive adhesive. By electrically connecting the heat sink layers 303-3 and 303-4 to the device substrate 302, the heat sink layers 303-3 and 303-4 are configured for transferring both heat and current. To be specific, when the power module is powered on, the heat sink layer 303-3 and the heat sink layer 303-4 transfer heat from the first power device chip 302-1 and the second power device chip 302-2 to the environment or external components, and also transfer current from the first power device chip 302-1 and the second power device chip 302-2 to the first winding 303-1 and the second winding 303-2. Thus the thermal flow of the power module 300 is optimized, as will be further illustrated beginning with FIG. 15.

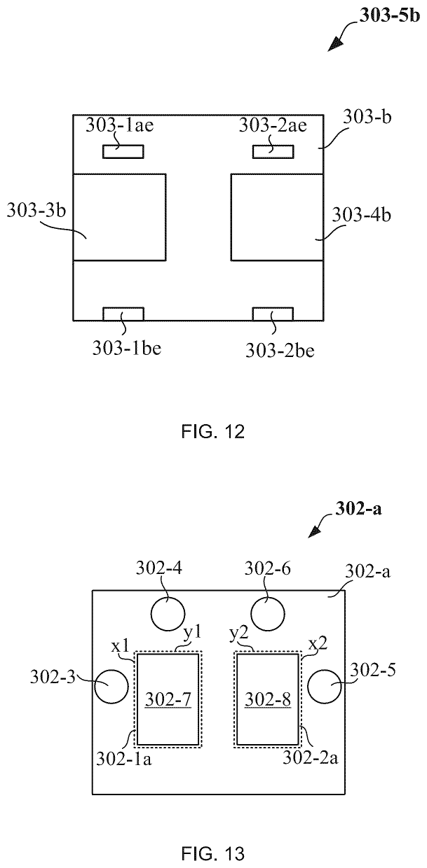

FIG. 12 shows a bottom view of the inductor assembly 303, i.e., the second surface 303-5b of the inductor assembly 303, in accordance with an embodiment of the present invention. In the example shown in FIG. 12, the first portion 303-1a of the first winding 303-1 has an end 303-1ae, and the second portion 303-1b of the first winding 303-1 has an end 303-1be. The end 303-1ae of the first portion 303-1a of the first winding 303-1 is exposed at the second surface 303-5b of the magnetic core 303-5 as shown in FIG. 12, and is electrically connected to the top heat layer 302-7. The end 303-1be of the second portion 303-1b of the first winding 303-1 is exposed at the second surface 303-5b of the magnetic core 303-5 and is electrically connected to the connecting pillar 302-4. In one embodiment, the end 303-1ae of the first portion 303-1a of the first winding 303-1 is physically attached to the surface of the top heat layer 302-7 by soldering or via a conductive adhesive, and the end 303-2be of the second winding 303-2 is physically attached to the connecting pillar 302-6 by soldering or via a conductive adhesive. It should be appreciated that the second winding 303-2 has the similar structure with the first winding 303-1 as shown in FIG. 11, and has an end 303-2ae electrically connected to the top heat layer 302-8 and another end 303-2be electrically connected to the connecting pillar 302-6. In one embodiment, the end 303-2ae of the second winding 303-2 is physically attached to the surface of the top heat layer 302-8 by soldering or via a conductive adhesive, and the end 303-2be of the second winding 303-2 is physically attached to the connecting pillar 302-6 by soldering or via a conductive adhesive.

FIG. 13 shows a top view of the device substrate 302 in accordance with an embodiment of the present invention. FIG. 13 shows a top surface 302-1a of the first power device chip 302-1 which is partially covered by the top heat layer 302-7, and a top surface 302-2a of the second power device chip 302-2 which is partially covered by the top heat layer 302-8. As shown in FIG. 13, the top surface 302-1a of the first power device chip 302-1 has a long edge x1 and a short edge y1, and the top surface 302-2a of the second power device chip 302-2 has a long edge x2 and a short edge y2. Different from the power module 20 described in previous embodiments in which the connecting pillars are arranged next to opposite edges of a top surface of the corresponding power device chip, in the embodiment of FIG. 13, the connecting pillars 302-3 and 302-4 of the power module 30 are arranged next to adjacent edges of the top surface 302-1a of the first power device chip 302-1, i.e., the connecting pillar 302-3 is placed next to the long edge x1 of the top surface 302-1a of the first power device chip 302-1, and the connecting pillar 302-4 is placed next to the short edge y1 of the top surface 302-1a of the first power device chip 302-1. Similarly, the connecting pillar 302-5 is placed next to the long edge x2 of the top surface 302-2a of the second power device chip 302-2, and the connecting pillar 302-6 is placed next to the short edge y2 of the top surface 302-2a of the second power device chip 302-2.

FIG. 14 shows a bottom view of the device substrate 302 in accordance with an embodiment of the present invention. As mentioned before, each of the first power device chip 302-1 and the second power device chip 302-2 integrates the switches M1, M2, the driver DR1 shown in FIG. 1 and other accessory circuits. Therefore, each of the first power device chip 302-1 and the second power device chip 302-2 has a plurality of pins including at least an input pin PVIN, at least one switching pin PSW1, at least one ground pin PGND, and a driving pin PDRV1 as shown in FIG. 14 (not all of the switching pins PSW1 and ground pins PGND are labeled in FIG. 14 for clarity of illustration). Taking the first power device chip 302-1 as an example, a common node of the switches M1 and M2 is connected to the at least one switching pin PSW1. To be specific, the first switch M1 has a first terminal coupled to the input pin PVIN (corresponding to the input terminal T1 in FIG. 1) to receive the input voltage Vin (shown in FIG. 1), a second terminal connected to the at least one switching pin PSW1 (corresponding to the switching terminal S1 in FIG. 1), and a control terminal configured to receive a first driving signal G1. The second switch M2 has a first terminal connected to the at least one switching pin PSW1, a second terminal connected to the ground pin PGND, and a control terminal configured to receive a second driving signal G2. The driver DR1 is coupled to the driving pin PDRV1 to receive a phase control signal 105 shown in FIG. 1, and to provide the first driving signal G1 and the second driving signal G2 based on the phase control signal 105. The plurality of pins of the first power device chip 302-1 and the second power device chip 302-2 are electrically connected to external circuits/devices/components via the bottom substrate 301. The bottom substrate 301 may be attached to a mainboard where the load (CPU, GPU, etc.) are located, and there may be circuits/devices/components on the mainboard providing the input voltage Vin, the phase control signal 105, and a ground reference GND that provides a common ground for the first power device chip 302-1 and the second power device chip 302-2 via the ground pins PGND.

In the example of FIG. 14, the second end of the connecting pillar 302-3 is connected to the bottom substrate 301 via a first switching terminal SSW1. Furthermore, the connecting pillar 302-3 and the heat sink layer 303-3 are electrically connected to the at least one switching pin PSW1 of the first power device chip 302-1 via conductive traces inside the bottom substrate 301. The second end of the connecting pillar 302-4 is connected to the bottom substrate 301 via a first output voltage terminal SVOUT1. The second end of the connecting pillar 302-5 is connected to the bottom substrate 301 via a second switching terminal SSW2. The connecting pillar 302-5 and the heat sink layer 303-4 are electrically connected to the at least one switching pin PSW2 of the second power device chip 302-2 via conductive traces inside the bottom substrate 301. The second end of the connecting pillar 302-6 is connected to the bottom substrate 301 via a second output voltage terminal SVOUT2. In some embodiments of the present invention, the connecting pillars 302-3, 302-4, 302-5 and 302-6 are soldered to the bottom substrate 301, and the first switching terminal SSW1, the first output voltage terminal SVOUT1, the second switching terminal SSW2 and the second output voltage terminal SVOUT2 are solder pastes connected to the ends of the connecting pillars 302-3, 302-4, 302-5 and 302-6. It should be appreciated that the connecting pillars 302-3, 302-4, 302-5 and 302-6 may be connected to the bottom substrate 301 directly, or by other connecting means known in the art, e.g., the connecting pillars 302-3, 302-4, 302-5 and 302-6 may be protruded out of the bottom surface 302-b of the device substrate 302 and are inserted to grooves of the bottom substrate 301.

As shown in FIG. 14, the first power device chip 302-1 further has signal pins PSIG1 which may be configured to transmit temperature monitoring signal, current monitoring signal, and other necessary signals for communicating between the first power device chip 302-1 and external circuits. The second power device chip 302-2 has signal pins PSIG2 which may be configured to transmit temperature monitoring signal, current monitoring signal, and other necessary signals for communicating between the second power device chip 302-2 and external circuits. In FIG. 14, the driving pin PDRV1 is illustrated as an example of the signal pins PSIG1, and the driving pin PDRV2 is illustrated as an example of the signal pins PSIG2. Other signal pins, like the pins for transmitting the temperature monitoring signal, the current monitoring signal, etc., are not specifically labeled for brevity. The discrete components 302-p together with the first power device chip 302-1 and the second power device chip 302-2 which are molded within the device substrate 302 have connecting terminals on the second surface of the device substrate 302. As shown in the embodiment of FIG. 14, each one of the discrete components 302-p, i.e., the capacitors and the resistors, has two pins or pads exposed at the second surface 302-b of device substrate 302, and is connected to the bottom substrate 301, wherein the discrete components 302-p are electrically connected to the first power device chip 302-1 and the second power device chip 302-2, and external components/circuits via the bottom substrate 301. Persons of ordinary skill in the art should know that the pins shown in FIG. 14 are for illustrating, which should not be limiting the present invention. The pin distribution on the second surface of the device substrate 302 is determined by the requirement of the application specs, and is varying in different applications.

FIG. 15 shows a cross-sectional view illustrating the power module 30 taken along CC′ line of FIG. 10 in accordance with an embodiment of the present invention. FIG. 16 shows a cross-sectional view illustrating the power module 30 taken along DD′ line of FIG. 10 in accordance with an embodiment of the present invention. As shown in FIG. 15, the plurality of pins of the first power device chip 302-1 and the second power device chip 302-2 are represented by the shaded regions shown in FIG. 15 and FIG. 16.

Referring back to FIG. 1, each one of the inductors has a first end coupled to the switching terminal S1 of the corresponding phase and a second end to provide the output voltage Vout. Taking the phase 102-1 as an example, in the power module 30, the switching terminal S1 is coupled to a first end of the inductor L-1 (corresponding to the first end 303-1ae of the first winding 303-1) actually through a path from the first power device chip 302-1 to the first portion 303-1a of the first winding 303-1, wherein the path has a certain resistance causing power loss. Arrows with solid lines in FIGS. 15 and 16 show a current flow path from the first power device chip 302-1 to the first portion 303-1a of the first winding 303-1. As shown in FIG. 15, a current flows from the first power device chip 302-1 to the bottom substrate 301 through the at least one switching pin PSW1, then flows to the connecting pillar 302-3 through the conductive traces inside the bottom substrate 301 and the first switching terminal SSW1, and then flows through the connecting pillar 302-3 to the heat sink layer 303-3. As shown in FIG. 16, the current further flows from the heat sink layer 303-3 to the top heat layer 302-7, and finally through the top heat layer 302-7 to the first portion 303-1a of the first winding 303-1. In the example of FIG. 15, a current flow path from the first power device chip 302-2 to the first portion 303-2a of the first winding 303-2 is similar to the current flow path from the first power device chip 302-1 to the first portion 303-1a of the first winding 303-1, and is not illustrated for brevity of description.

As mentioned before, in the embodiments of the power module 20 shown in FIGS. 2-7, the first end 203-1ae of the first winding 203-1 (corresponding to the first end of the inductor L-1 in FIG. 1) is electrically connected to the at least one switching pin PSW1 (corresponding to the switching terminal S1 in FIG. 1) of the first power device chip 202-1 via the connecting pillar 202-3, the first switching terminal SSW1, and the conductive traces inside the bottom substrate 201. Since the connecting pillar 202-3 is placed next to a short edge of the top surface of the first power device chip 202-1, the conductive traces inside the bottom substrate 201 connect the first switching terminal SSW1 and the at least one switching pin PSW1 along a long edge of the top surface of the first power device chip 202-1, causing the conductive traces inside the bottom substrate 201 to be long, which is not good for reducing package resistance of the power module 20. With regard to the power module 30, since the heat sink layers 303-3 and 303-4 and the top heat layers 302-7 and 302-8 are much thicker than the conductive traces inside the bottom substrate 301, using the heat sink layers 303-3 and 303-4 and the top heat layers 302-7 and 302-8 to conduct current provides the power module 30 with a lower package resistance. Furthermore, in the power module 30, the connecting pillars 302-3 and 302-5 are placed next to the long edge x1 of the top surface 302-1a of the first power device chip 302-1 and the long edge x2 of the top surface 302-2a of the second power device chip 302-2 respectively as mentioned before in FIG. 13, thus the conductive traces inside the bottom substrate 301 connecting the switching pins PSW1 and the first switching terminal SSW1 and the second switching terminal SSW2 are shorter.

Besides, thermal performance of the power module 30 is also enhanced since heat of the power module 30 is mostly dissipated through conductors which have larger area (including the top heat layers 302-7 and 302-8, the heat sink layers 303-3 and 303-4, the first winding 302-1 and the second winding 302-2) than the thin conductive traces.

Still referring to FIGS. 15 and 16, arrows with dashed lines 31-35 show main heat flow paths of the power module 30. As shown by the arrows 31 in FIG. 15, heat produced by the device substrate 302 is dissipated through the connecting pillars 302-3 and 302-5, and then through the heat sink layer 303-3 and the second heat sink layer 303-4. As shown by the arrow 34 in FIG. 16, the heat produced by the device substrate 302 is further dissipated through the connecting pillars 302-4 and 302-6, then through the first winding 303-1 and the second winding 303-2, and through the magnetic core 303-5 to the first surface 303-5a the inductor assembly 303 (the connecting pillar 302-6 and the second winding 303-2 are not shown in FIG. 16). As shown by the arrow 32 in FIG. 15, heat produced by the first power device chip 302-1 is dissipated through the top heat layer 302-7, and then through the heat sink layer 303-3. Since the connecting pillar 302-3 is connected to the at least one switching pin PSW1 via the conductive traces inside the bottom substrate 301 and the first switching terminal SSW1, the heat of the first power device chip 302-1 is further dissipated through the conductive traces inside the bottom substrate 301, the first switching terminal SSW1, the connecting pillar 302-3 and the first winding 303-1 as shown by the arrow 33 in FIG. 15. As shown by the arrow 35 in FIG. 16, the heat produced by the first power device chip 302-1 is further dissipated through the top heat layer 302-7, then through the first winding 303-1, and then through the magnetic core 303-5 to the first surface 303-5a of the inductor assembly 303. Heat of the second power device chip 302-2 is dissipated in the same way with the heat of the first power device chip 302-1, and is not discussed for the brevity of description. It is to be noted that, the arrows 31-33 in FIG. 15 only illustrate the heat flow paths from heat sources to the heat sink layer 303-3 and the heat sink layer 303-4. When the heat produced by the first power device chip 302-1, the second power device chip 302-2 and the device substrate 302 flows to the heat sink layer 303-3 and the heat sink layer 303-4, then the heat is partially further dissipated through the heat sink layer 303-3 and the heat sink layer 303-4 directly to the top of the inductor assembly 303, and partially dissipated through the heat sink layer 303-3 and the heat sink layer 303-4 to the magnetic core 303-5, and then finally to the first surface 303-5a of the inductor assembly 303.

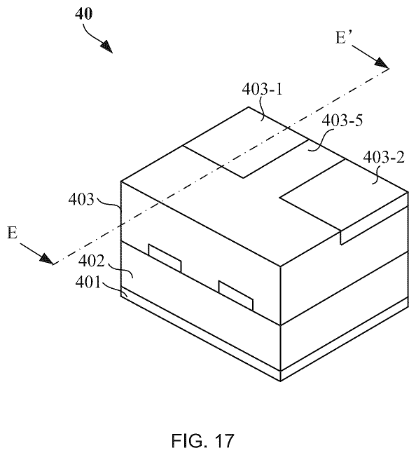

FIG. 17 shows a power module 40 for a dual-phase power converter in accordance with another embodiment of the present invention. The power module 40 may serve as the power stage 102 of FIG. 1, with N=2. The power module 40 includes a bottom substrate 401, a device substrate 402 and an inductor assembly 403. The bottom substrate 401 is arranged at the bottom of the power module 40, having a first surface facing the device substrate 402 and a second surface opposite to the first surface for external connection. The device substrate 402 is arranged on the bottom substrate 401. The inductor assembly 303 is arranged on the device substrate 402, thus the inductors L (e.g., L-1 and L-2) are integrated in the inductor assembly 403. Different from the power modules 20 and 30 illustrated in previous embodiments, a first winding 403-1 and a second winding 403-2 embedded in a magnetic core 403-5 of the inductor assembly 403 also work as heat sinks, thus additional heat sink layers could be omitted in the power module 40.

In one embodiment, the second surface of the bottom substrate 401 of the power module 40 comprises a first output voltage pad area and a second output voltage pad area, an input pad area, a ground pad area and a signal pad area, wherein structure and connection of the pad areas on the second surface of the bottom substrate 401 are same as the pad areas on the second surface 201-b of the bottom surface 201 described previously in FIG. 8, and is not discussed for the brevity of description.

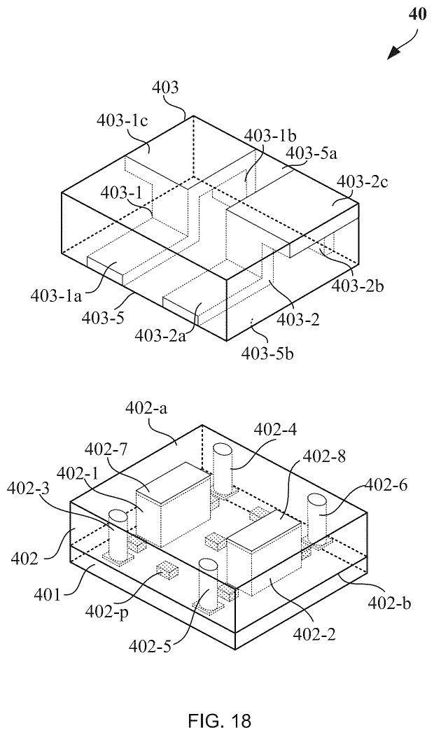

FIG. 18 shows a disassembled and perspective view illustrating the power module 40 of FIG. 17. As shown in FIG. 18, the device substrate 402 has a first surface 402-a and a second surface 402-b opposite to the first surface 302-a, and the device substrate 402 comprises a first power device chip 402-1, a second power device chip 402-2, a top heat layer 402-7 at least partially covering the first power device chip 402-1, and a top heat layer 402-8 at least partially covering the second power device chip 402-2, wherein each of the top heat layers 402-7 and 402-8 has a surface exposed at the first surface 402-a of the device substrate 402. In the example of FIG. 18, a switching pin of the first power device chip 402-1 is electrically coupled to the top heat layer 402-7 via conductive traces in the bottom substrate 401, the connecting pillar 402-3 and the first winding 403-1, and similarly, a switching pin of the second power device chip 402-2 is electrically coupled to the top heat layer 402-8 via conductive traces in the bottom substrate 401, the connecting pillar 402-5 and the second winding 403-2, which will be further illustrated beginning with FIG. 20. The device substrate 402 further comprises connecting pillars 402-3, 402-4, 402-5, and 402-6, and a plurality of discrete components 402-p, wherein all these components of the device substrate 402 are at least partially embedded within the device substrate 402. Each of the connecting pillars 402-3, 402-4, 402-5, and 402-6 has a first end exposed at the first surface 4002-a of the device substrate 402 and a second end exposed at the second surface 402-b of the device substrate 402. Detailed structure and placement of which are same as the connecting pillars 202-3, 202-4, 202-5, and 202-6 and the plurality of discrete components 202-p of the power module 20, and are not discussed for the brevity of description.

As shown in FIG. 18, the first winding 403-1 and the second winding 403-2 are at least partially embedded within the magnetic core 403-5, i.e., each of the first winding 403-1 and the second winding 403-2 may have at least one end exposed at one surface of the magnetic core 403-5. The first winding 403-1 and the magnetic core 403-5 form the first inductor L-1 as shown in FIG. 1. The second winding 403-2 and the magnetic core 403-5 form the second inductor L-2 as shown in FIG. 1. In the example shown in FIG. 18, the first winding 403-1 has a first portion 403-1a, a second portion 403-1b, and a third portion 403-1c connecting the first portion 403-1a and the second portion 403-1b. Similarly, the second winding 403-2 has a first portion 403-2a, a second portion 403-2b, and a third portion 403-2c connecting the first portion 403-2a and the second portion 403-2b. The third portion 403-1c of the first winding 403-1 and the third portion 403-2c of the second winding 403-2 are parallel to each other.

As shown in FIG. 18, a top surface of the third portion 403-1c of the first winding 403-1 and a top surface of the third portion 403-2c of the second winding 403-2 are exposed at a first surface 403-5a of the magnetic core 403-5, and each of the first winding 403-1 and the second winding 403-2 has two ends exposed at a second surface 403-5b of the magnetic core 403-5, wherein the second surface 403-5b is opposite to the first surface 403-5a, and the surfaces 403-5a and 403-5b of the magnetic core 403-5 are also referred as surfaces of the inductor assembly 403. In one embodiment, the first winding 403-1 and the second winding 403-2 further have some parts exposed at other surfaces of the magnetic core 403-5. In one embodiment, the first winding 403-1 and the second winding 403-2 are made of copper.

In the example of FIG. 18, when the bottom substrate 401, the device substrate 402 and the inductor assembly 403 are assembled together, the second surface 402-b of the device substrate 402 faces the first surface of the bottom substrate 401, and the second surface 403-5b of the inductor assembly 401 faces the first surface 402-a of the device substrate 402. The first portion 403-1a of the first winding 403-1 is electrically connected to the connecting pillar 402-3 and the top heat layer 402-7, and the second portion 403-1b of the first winding 403-1 is electrically connected to the connecting pillar 402-4. Similarly, the first portion 403-2a of the second winding 403-2 is electrically connected to the connecting pillar 402-5 and the top heat layer 402-8, and the second portion 403-2b of the second winding 403-2 is electrically connected to the connecting pillar 402-6.

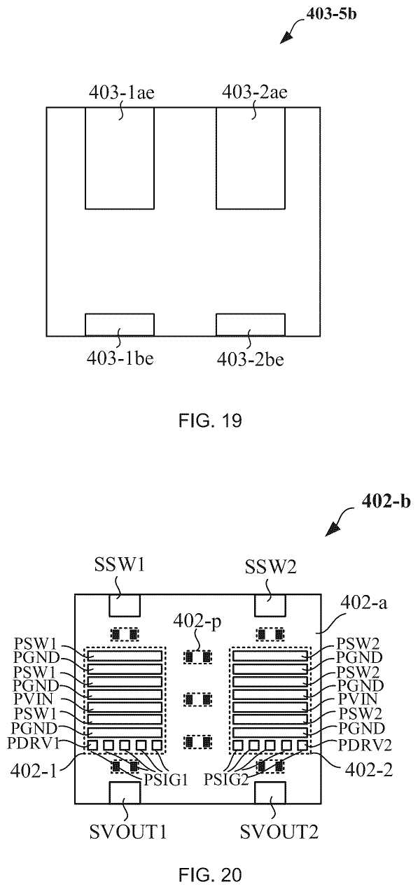

FIG. 19 shows a bottom view of the inductor assembly 403, i.e., the second surface 403-5b of the inductor assembly 403, in accordance with an embodiment of the present invention. In the example shown in FIG. 19, a bottom surface of the first portion 403-1a of the first winding 403-1 forms an end 403-1ae of the first winding 403-1, and a bottom surface of the second portion 403-2a of the second winding 403-2 forms an end 403-2ae of the second winding 403-1. Similarly, a bottom surface of the second portion 403-1b of the first winding 403-1 forms an end 403-1be of the first winding 403-1, and a bottom surface of the second portion 403-2b of the second winding 403-2 forms an end 403-2be of the second winding 403-2. The end 403-1ae of the first winding 403-1 is exposed at the second surface 403-5b of the magnetic core 403-5 as shown in FIG. 19, and is electrically connected to the first end of the connecting pillar 402-3 and the top heat layer 402-7. The end 403-1be of the first winding 403-1 is exposed at the second surface 403-5b of the magnetic core 403-5 as shown in FIG. 19, and is electrically connected to the first end of the connecting pillar 402-4. It should be appreciated that the second winding 403-2 has similar structure with the first winding 403-1 as shown in FIG. 18, i.e., the second winding 403-2 has one end 403-2ae electrically connected to the first end of the connecting pillar 302-5 and the top heat layer 402-8, and has another end 403-2be electrically connected to the first end of the connecting pillar 402-6. In one embodiment, the ends 403-1ae and 403-1be of the first winding 403-1 are physically attached to the first end of the connecting pillar 402-3 and the first end of the connecting pillar 402-4 respectively by soldering or via a conductive adhesive, and the ends 403-2ae and 403-2be of the second winding 403-2 are physically attached to the first end of the connecting pillar 402-5 and the first end of the connecting pillar 402-6 by soldering or via a conductive adhesive.

FIG. 20 shows a bottom view of the device substrate 402, i.e., the second surface 402-b of the device substrate 402, in accordance with an embodiment of the present invention. As mentioned before, each of the first power device chip 402-1 and the second power device chip 402-2 integrates the switches M1, M2, the driver DR1 shown in FIG. 1 and other accessory circuits not shown in FIG. 1. Therefore, each of the first power device chip 402-1 and the second power device chip 402-2 has a plurality of pins which function in the same way with the plurality of pins of the power device chips 202-1 and 202-2 of the power module 20 illustrated in FIG. 7, wherein a common node of the switches M1 and M2 is connected to the at least one switching pin PSW1. In the example of FIG. 20, the device substrate 402 further comprises the first switching terminal SSW1, the second switching terminal SSW2, the first output voltage terminal SVOUT1 and the second output voltage terminal SVOUT2. The connecting pillar 402-3 is connected to the bottom substrate 401 via the first switching terminal SSW1, the connecting pillar 402-4 is connected to the bottom substrate 301 via the first output voltage terminal SVOUT1, the connecting pillar 402-5 is connected to the bottom substrate 401 via the second switching terminal SSW2, and the connecting pillar 402-6 is connected to the bottom substrate 401 via the second output voltage terminal SVOUT2.

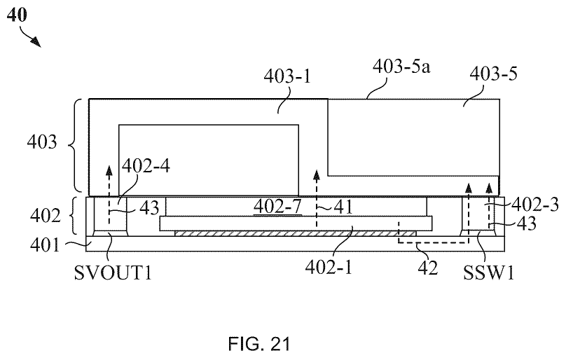

FIG. 21 shows a cross-sectional view illustrating the power module 40 taken along EE′ line of FIG. 17 in accordance with an embodiment of the present invention. As shown in FIG. 21, the first power device chip 402-1 has a first surface partially covered by the top heat layer 402-7 and a second surface connected to the bottom substrate 401 through the plurality of pins as mentioned before in FIG. 20, wherein the plurality of pins are represented by the shaded regions shown in FIG. 21. In the example of FIG. 21, arrows 41-43 with dashed lines show main heat flow paths of the power module 40. As shown by the arrow 41, heat of the power device chip 402-1 is dissipated through the top heat layer 402-7 to the first winding 403-1. Since the connecting pillar 402-3 is connected to the at least one switching pin PSW1 via the conductive traces inside the bottom substrate 401 and the first switching terminal SSW1, the heat of the first power device chip 402-1 is further dissipated through the conductive traces, the first switching terminal SSW1, the connecting pillar 402-3 and the first winding 403-1 as shown by the arrow 42. Heat of the second power device chip 402-2 is dissipated in the same way with the heat of the first power device chip 402-1, and is not discussed for the brevity of description. As shown by the arrows 43 in FIG. 21, heat of the device substrate 402 is dissipated through the connecting pillars 402-3, 402-4, 402-5, and 402-6, the first winding 403-1 and the second winding 403-2 (the connecting pillars 402-5 and 402-6, and the second winding 403-2 are not shown in FIG. 21). Therefore, in the power module 40, the first winding 403-1 and the second winding 403-2 also work as heat sinks conducting both current and thermal, which simplifies the structure of the power module 40 and save cost since no additional heat sink layers are needed. It is to be noted that, the arrows 41-43 in FIG. 21 only illustrate the heat flow paths from heat sources to the windings, when the heat produced by the first power device chip 402-1, the second power device chip 402-2 and the device substrate 402 flows to the first winding 403-1 and the second winding 403-2, then the heat is partially further dissipated through the first winding 403-1 and the second winding 403-2 directly to the first surface 403-5a of the inductor assembly 403, and partially further dissipated through the first winding 403-1 and the second winding 403-2 to the magnetic core 403-5, and then finally to the first surface 403-5a of the inductor assembly 403.

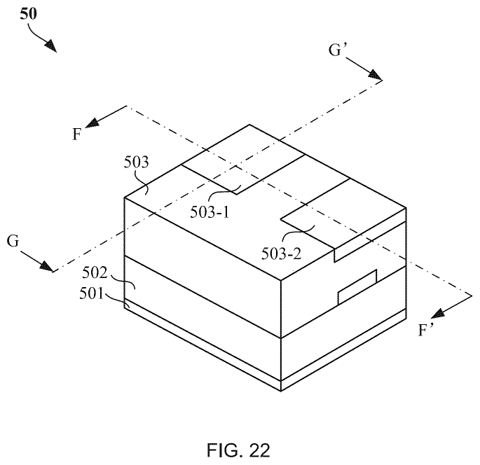

FIG. 22 shows a power module 50 for a dual-phase power converter in accordance with another embodiment of the present invention. The power module 50 may serve as the power stage 102 of FIG. 1, with N=2. The power module 50 includes a bottom substrate 501, a device substrate 502 and an inductor assembly 503. The bottom substrate 501 is arranged at the bottom of the power module 50, having a first surface facing the device substrate 502 and a second surface opposite to the first surface for external connection. The device substrate 502 is arranged on the bottom substrate 501. The inductor assembly 503 is arranged on the device substrate 502, thus the inductors L are integrated in the inductor assembly 503. Similar to the power module 40, additional heat sink layers are omitted in the power module 50.

In one embodiment, the second surface of the bottom substrate 501 of the power module 50 comprises a first output voltage pad area and a second output voltage pad area, an input pad area, a ground pad area and a signal pad area, wherein structure and connection of the pad areas on the second surface of the bottom substrate 501 are same as the pad areas on the second surface 201-b of the bottom surface 201 described previously in FIG. 8, and is not discussed for the brevity of description.

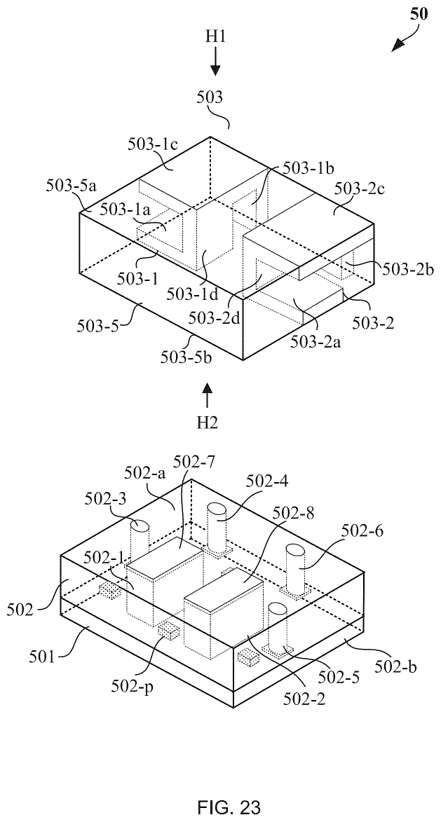

FIG. 23 shows a disassembled and perspective view illustrating the power module 50 of FIG. 22. As shown in FIG. 23, the device substrate 502 has a first surface 502-a and a second surface 502-b opposite to the first surface 502-a, and the device substrate 502 comprises a first power device chip 502-1, a second power device chip 502-2, a top heat layer 502-7 at least partially covering the first power device chip 502-1, a top heat layer 502-8 at least partially covering the second power device chip 502-2, connecting pillars 502-3, 502-4, 502-5, and 502-6, and a plurality of discrete components 502-p, wherein all these components of the device substrate 502 are at least partially embedded within the device substrate 502. Each of the connecting pillars 502-3, 502-4, 502-5, and 502-6 has a first end exposed at the first surface 502-a of the device substrate 502. In the example of FIG. 23, a switching pin of the first power device chip 502-1 is electrically coupled to the top heat layer 502-7 via the device substrate, the bottom substrate, the connecting pillar 502-3 and the first winding 502-1, and similarly, a switching pin of the second power device chip 502-2 is electrically coupled to the top heat layer 502-8 via the device substrate, the bottom substrate, the connecting pillar 502-5 and the second winding 502-2, which will be further illustrated beginning with FIG. 25. Detailed structure of the device substrate 502 is same as the device substrate 302 of the power module 30, and is not discussed for the brevity of description.

As shown in FIG. 23, the first winding 503-1 and the second winding 503-2 are at least partially embedded within the magnetic core 503-5, i.e., each of the first winding 403-1 and the second winding 403-2 may have at least one end exposed at one surface of the magnetic core 403-5. The first winding 503-1 and the magnetic core 503-5 form the first inductor L-1 as shown in FIG. 1. The second winding 503-2 and the magnetic core 503-5 form the second inductor L-2 as shown in FIG. 1. The magnetic core 503-5 has a first surface 503-5a and a second surface 503-5b opposite to the first surface 503-5a, and the surfaces of the magnetic core 503-5 are also referred as surfaces of the inductor module 503. In the example shown in FIG. 23, the first winding 503-1 has a first portion 503-1a, a second portion 503-1b, a third portion 503-1c, and a fourth portion 503-1d, wherein the first portion 503-1a has a bottom surface exposed at the second surface 503-5b of the magnetic core 503-5, the first portion 503-1a and the third portion 503-1c are connected via the fourth portion 503-1d which is inside the magnetic core 503-5, and the second portion 503-1b is connected to the third portion 503-1c and has a bottom surface exposed at the second surface 503-5b of the magnetic core 503-5. Similarly, the second winding 503-2 has a first portion 503-2a, a second portion 503-2b, a third portion 503-2c, and a fourth portion 503-2d which are connected in the same way with the first winding 503-1. As shown in FIG. 23, a top surface of the third portion 503-1c of the first winding 503-1 and a top surface of the third portion 503-2c of the second winding 503-2 are exposed at the first surface 503-5a of the magnetic core 503-5, and the fourth portions 503-1d and 503-2d are vertical to the first surface 503-5a of the magnetic core 503-5. In one embodiment, the first winding 503-1 and the second winding 503-2 further has some parts exposed at other surfaces of the magnetic core 503-5. In a vertical view of the inductor assembly 503 (i.e., viewed from a direction which is perpendicular to the first surface 503-5a of the inductor assembly 503, e.g., in the direction of an arrow H1 or an arrow H2 shown in FIG. 23), the first portion 503-1a and the third portion 503-1c of the first winding 503-1 are at least partially overlapped, and the first portion 503-2a and the third portion 503-2c of the second winding 503-2 are at least partially overlapped. In one embodiment, the first winding 503-1 and the second winding 503-2 are made of copper.

In the example of FIG. 23, when the bottom substrate 501, the device substrate 502 and the inductor assembly 503 are assembled together, the first portion 503-1a of the first winding 503-1 is electrically connected to both the connecting pillar 502-3 and the top heat layer 502-7, and the second portion 503-1b of the first winding 503-1 is electrically connected to the connecting pillar 502-4. Similarly, the first portion 503-2a of the second winding 503-2 is electrically connected to both the connecting pillar 502-5 and the top heat layer 502-8, and the second portion 503-2b of the second winding 503-2 is electrically connected to the connecting pillar 502-6.

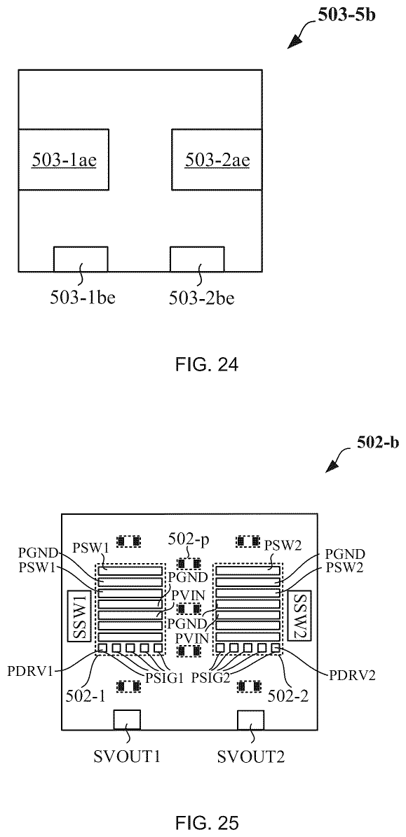

FIG. 24 shows a bottom view of the inductor assembly 503, i.e., the second surface 503-5b of the inductor assembly 503, in accordance with an embodiment of the present invention. As shown in FIG. 24, the bottom surface of the first portion 503-1a of the first winding 503-1 forms an end 503-1ae of the first winding 503-1, and the bottom surface of the second portion 503-2a of the second winding 503-2 forms an end 503-2ae of the second winding 503-1. The bottom surface of the second portion 503-1b of the first winding 503-1 forms an end 503-1be of the first winding 503-1, and the bottom surface of the second portion 503-2b of the second winding 503-2 forms an end 503-2be of the second winding 503-2. The end 503-1ae of the first winding 503-1 is exposed at the second surface 503-5b of the magnetic core 503-5 as shown in FIG. 24, and is physically attached to the surface of the top heat layer 502-7 and the first end of the connecting pillar 502-3 by soldering or via a conductive adhesive. The end 503-1be of the first winding 503-1 is exposed at the second surface 503-5b of the magnetic core 503-5 as shown in FIG. 24, and is physically attached to the first end of the connecting pillar 502-4 by soldering or via a conductive adhesive. Similarly, the end 503-2ae of the second winding 503-2 is physically attached to the surface of the top heat layer 502-8 and the first end of the connecting pillar 502-5 by soldering or via a conductive adhesive, and the end 503-2be of the second winding 503-2 is physically attached to the first end of the connecting pillar 502-6 by soldering or via a conductive adhesive.

FIG. 25 shows a bottom view of the device substrate 502, i.e., the second surface 502-b of the device substrate 502, in accordance with an embodiment of the present invention. As shown in FIG. 25, each of the first power device chip 502-1 and the second power device chip 502-2 has a plurality of pins which function in the same way with the plurality of pins of the power device chips 302-1 and 302-2 of the power module 30 illustrated in FIG. 14, and are not discussed for the brevity of description. In the example of FIG. 25, the device substrate 502 further comprises the first switching terminal SSW1, the second switching terminal SSW2, the first output voltage terminal SVOUT1 and the second output voltage terminal SVOUT2. The connecting pillar 502-3 is connected to the bottom substrate 501 via the first switching terminal SSW1, the connecting pillar 502-4 is connected to the bottom substrate 501 via the first output voltage terminal SVOUT1, the connecting pillar 502-5 is connected to the bottom substrate 501 via the second switching terminal SSW2, and the connecting pillar 502-6 is connected to the bottom substrate 501 via the second output voltage terminal SVOUT2.

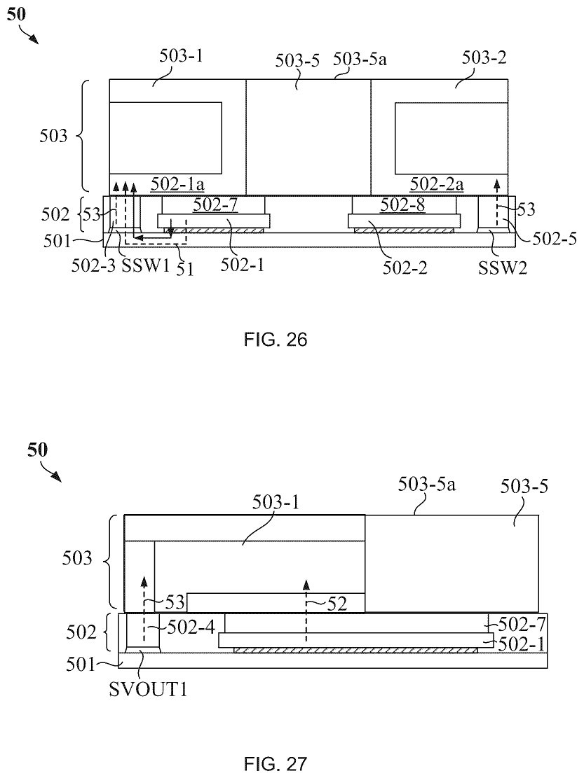

FIG. 26 shows a cross-sectional view illustrating the power module 50 taken along FF′ line of FIG. 22 in accordance with an embodiment of the present invention. FIG. 27 shows a cross-sectional view illustrating the power module 30 taken along GG′ line of FIG. 22 in accordance with an embodiment of the present invention. As shown in FIG. 26, the first power device chip 502-1 has a first surface covered by the top heat layer 502-7 and a second surface connected to the bottom substrate 501 through the plurality of pins as mentioned before in FIG. 25, and the second power device chip 502-2 has a first surface covered by the top heat layer 502-8 and a second surface connected to the bottom substrate 501 through the plurality of pins, wherein the plurality of pins are represented by the shaded regions shown in FIG. 26 and FIG. 27.

Arrows with solid lines in FIG. 26 show a current flow path from the first power device chip 502-1 to the first portion 503-1a of the first winding 503-1 of the power module 50. As shown in FIG. 26, current flows from the first power device chip 502-1 to the bottom substrate 501 through the at least one switching pin PSW1, then flows to the connecting pillar 502-3 through the conductive traces inside the bottom substrate 501 and the first switching terminal SSW1, and then flows through the connecting pillar 502-3 to the first portion 503-1a of the first winding 503-1.

In the example of FIGS. 26 and 27, arrows 51-53 with dashed lines show main heat flow paths of the power module 50. Since the connecting pillars 502-3 is connected to the at least one switching pin PSW1 of the first device chip 502-1 via the conductive traces inside the bottom substrate 501 and the first switching terminal SSW1, heat of the first power device chip 502-1 is dissipated through the conductive traces, the first switching terminal SSW1, the connecting pillar 502-3 and the first winding 503-1 as shown by the arrow 51. As shown by the arrow 52 in FIG. 27, the heat of the first power device chip 502-1 is further dissipated through the top heat layer 502-7 and then through the first winding 503-1. Heat of the second power device chip 502-2 is dissipated in the same way with the heat of the first power device chip 502-1, and is not discussed for the brevity of description. As shown by the arrows 53 in FIGS. 26 and 27, heat of the device substrate 502 is dissipated through the connecting pillars 502-3, 502-4, 502-5, and 502-6, the first winding 503-1, and the second winding 503-2 (the connecting pillar 502-6 is not shown in FIG. 27). It is to be noted that, the arrows 51-53 only illustrate the heat flow paths from heat sources to the windings, when the heat produced by the first power device chip 502-1, the second power device chip 502-2 and the device substrate 502 flows to the first winding 503-1 and the second winding 503-2, then the heat is partially dissipated through the first winding 503-1 and the second winding 503-2 directly to the first surface 503-5a of the inductor assembly 503, and partially dissipated through the first winding 503-1 and the second winding 503-2 to the magnetic core 503-5, and then finally to the first surface 503-5a of the inductor assembly 503.

Similar to the power module 40, the first winding 503-1 and the second winding 503-2 of the power module 50 also work as heat sinks conducting both current and thermal, which simplifies the structure of the power module 50 and save cost since no additional heat sink layers are needed. Besides, since the connecting pillars 502-3 and 502-5 are placed next to the long edges of top surfaces of the first power device chip 502-1 and the second power device chip 502-2, the power module 50 also provides shorter heat flow paths along the conductive traces inside the bottom substrate 501, which means the thermal performance of the power module 50 is also enhanced similar to the power module 30.

Obviously many modifications and variations of the present invention are possible in light of the above teachings. It is therefore to be understood that within the scope of the appended claims the invention may be practiced otherwise than as specifically described. It should be understood, of course, the foregoing disclosure relates only to a preferred embodiment (or embodiments) of the invention and that numerous modifications may be made therein without departing from the spirit and the scope of the invention as set forth in the appended claims. Various modifications are contemplated and they obviously will be resorted to by those skilled in the art without departing from the spirit and the scope of the invention as hereinafter defined by the appended claims as only a preferred embodiment(s) thereof has been disclosed.

What is claimed is:

1. A power module, comprising:
a device substrate having a first surface and a second surface opposite to the first surface of the device substrate, wherein the device substrate comprises a first power device chip, a second power device chip, a first top heat layer at least partially covering the first power device chip, and a second top heat layer at least partially covering the second power device chip, wherein each of the first top heat layer and the second top heat layer has a surface exposed at the first surface of the device substrate; and
an inductor assembly having a first surface and a second surface opposite to the first surface of the inductor assembly, the inductor assembly comprising:
a magnetic core;
a first winding and a second winding at least partially embedded within the magnetic core, wherein each of the first winding and the second winding has a first end and a second end exposed at the second surface of the inductor assembly; and
a first heat sink layer and a second heat sink layer wrapping at least partial of the inductor assembly; wherein
the first heat sink layer and the first end of the first winding are electrically connected to the first top heat layer, and the second heat sink layer and the first end of the second winding are electrically connected to the second top heat layer.

2. The power module of claim 1, further comprising:
a bottom substrate having a first surface and a second surface opposite to the first surface of the bottom substrate, the second surface of the bottom substrate comprising:
a first output voltage pad area having at least one pad;
a second output voltage pad area having at least one pad;
an input pad area having at least one pad;
a ground pad area having at least one pad; and
a signal pad area having at least two pads; wherein
the device substrate is arranged on the bottom substrate with the second surface of the device substrate facing the first surface of the bottom substrate, and the inductor assembly is arranged on the device substrate with the second surface of the inductor assembly facing the first surface of the device substrate; and wherein
the second end of the first winding is electrically connected to the at least one pad of the first output voltage pad area via the device substrate, and the second end of the second winding is electrically connected to the at least one pad of the second output voltage pad area via the device substrate.

3. The power module of claim 2, wherein each one of the first power device chip and the second power device chip comprises:
a driver;
a first switch, a second switch, and a switching pin electrically connected to a common node of the first switch and the second switch;
an input pin electrically connected to the at least one pad of the input pad area;
a ground pin electrically connected to the at least one pad of the ground pad area; and
a driving pin electrically connected to one pad of the at least two pads of the signal pad area; wherein
the first switch has a first terminal coupled to the input pin, a second terminal coupled to the switching pin, and a control terminal configured to receive a first driving signal, and the second switch has a first terminal coupled to the switching pin, a second terminal coupled to the ground pin, and a control terminal configured to receive a second driving signal; and wherein
the driver is coupled to the driving pin to receive a phase control signal, and to provide the first driving signal and the second driving signal based on the phase control signal.

4. The power module of claim 1, wherein:
each of the first power device chip and the second power device chip comprises a first switch, a second switch, and a switching pin electrically connected to a common node of the first switch and the second switch; and wherein
the device substrate further comprises a first connecting pillar and a second connecting pillar, wherein the first connecting pillar is electrically connected to the switching pin of the first power device chip, the second connecting pillar is electrically connected to the switching pin of the second power device chip.

5. The power module of claim 4, wherein:
the device substrate further comprises a third connecting pillar and a fourth connecting pillar, wherein the second end of the first winding is electrically connected to the third connecting pillar, and the second end of the second winding is electrically connected to the fourth connecting pillar.

6. The power module of claim 4, wherein:
the first power device chip has a top surface partially covered by the first top heat layer, and the second power device chip has a top surface partially covered by the second top heat layer, wherein each of the top surfaces of the first power device chip and the second power device chip has a short edge and a long edge, the first connecting pillar is placed next to the long edge of the top surface of the first power device chip, and the second connecting pillar is placed next to the long edge of the top surface of the second power device chip; and wherein
the first heat sink layer is electrically connected to the first connecting pillar, and the second heat sink layer is electrically connected to the second connecting pillar.

7. The power module of claim 6, wherein the first heat sink layer is physically attached to an end of the first connecting pillar by soldering or via a conductive adhesive, and wherein the second heat sink layer is physically attached to an end of the second connecting pillar by soldering or via a conductive adhesive.

8. The power module of claim 1, wherein:
each of the first power device chip and the second power device chip comprises a first switch, a second switch, and a switching pin electrically connected to a common node of the first switch and the second switch; and wherein
the switching pin of the first power device chip is electrically connected to the first top heat layer, the first heat sink layer and the first end of the first winding;
the switching pin of the second power device chip is electrically connected to the second top heat layer, the second heat sink layer and the first end of the second winding.

9. The power module of claim 1, wherein:
the first heat sink layer has a first portion covering at least partial of the second surface of the inductor assembly and a second portion covering at least partial of a third surface of the inductor assembly, wherein the third surface of the inductor assembly is vertical to the first surface and the second surface of the inductor assembly; and wherein
the second heat sink layer has a first portion covering at least partial of the second surface of the inductor assembly and a second portion covering at least partial of a fourth surface of the inductor assembly, wherein the fourth surface of the inductor assembly is vertical to the first surface and the second surface of the inductor assembly and opposite to the third surface of the inductor assembly.

10. The power module of claim 9, wherein the first portion of the first heat sink layer and the first end of the first winding are physically attached to the surface of the first top heat layer by soldering or via a conductive adhesive, and wherein the first portion of the second heat sink layer and the first end of the second winding are physically attached to the surface of the second top heat layer by soldering or via a conductive adhesive.

11. A power module, comprising:
an inductor assembly having a first surface and a second surface opposite to the first surface of the inductor assembly, wherein the inductor assembly comprises a magnetic core, a first winding and a second winding at least partially embedded within the magnetic core, and wherein each of the first winding and the second winding has a first end and a second end exposed at the second surface of the inductor assembly; and
a device substrate having a first surface and a second surface opposite to the first surface of the device substrate, the device substrate comprising:
a first power device chip and a second power device chip at least partially embedded within the device substrate, wherein each of the first power device chip and the second power device chip has a first switch, a second switch and a switching pin electrically connected to a common node of the first switch and the second switch;
a first top heat layer at least partially covering the first power device chip;
a second top heat layer at least partially covering the second power device chip;
a first connecting pillar electrically connected to the switching pin of the first power device chip; and
a second connecting pillar electrically connected to the switching pin of the second power device chip; wherein
the first end of the first winding is electrically connected to the first top heat layer and the first connecting pillar, and the first end of the second winding is electrically connected to the second top heat layer and the second connecting pillar.

12. The power module of claim 11, further comprising:
a bottom substrate having a first surface and a second surface opposite to the first surface of the bottom substrate, wherein the second surface of the bottom substrate comprises a first output voltage pad area and a second output voltage pad area, each of the first output voltage pad area and the second output voltage pad area having at least one pad; wherein
the device substrate is arranged on the bottom substrate with the second surface of the device substrate facing the first surface of the bottom substrate, and the inductor assembly is arranged on the device substrate with the second surface of the inductor assembly facing the first surface of the device substrate.

13. The power module of claim 12, wherein the second surface of the bottom substrate further comprises an input pad area having at least one pad, a ground pad area having at least one pad, and a signal pad area having at least two pads, and wherein each of the first power device chip and the second power device chip further comprises:
a driver;
an input pin electrically connected to the at least one pad of the input pad area;
a ground pin electrically connected to the at least one pad of the ground pad area; and
a driving pin electrically connected to one pad of the at least two pads of the signal pad area; wherein
the first switch has a first terminal coupled to the input pin, a second terminal coupled to the switching pin, and a control terminal configured to receive a first driving signal, and the second switch has a first terminal coupled to the switching pin, a second terminal coupled to the ground pin, and a control terminal configured to receive a second driving signal; and wherein
the driver is coupled to the driving pin to receive a phase control signal, and to provide the first driving signal and the second driving signal based on the phase control signal.

14. The power module of claim 12, wherein:
the device substrate further comprises a third connecting pillar and a fourth connecting pillar; and wherein
the second end of the first winding is electrically connected to the at least one pad of the first output voltage pad area via the third connecting pillar, and the second end of the second winding is electrically connected to the at least one pad of the second output voltage pad area via the fourth connecting pillar.

15. The power module of claim 11, wherein each of the first winding and the second winding comprises:
a first portion providing the first end of the corresponding winding;
a second portion providing the second end of the corresponding winding; and
a third portion having a top surface exposed at the first surface of the inductor assembly.

16. The power module of claim 15, wherein in a vertical view of the inductor assembly, the first portion and the third portion of the first winding are at least partially overlapped, and the first portion and the third portion of the second winding are at least partially overlapped.

17. The power module of claim 16, wherein:
the first power device chip has a top surface partially covered by the first top heat layer, and the second power device chip has a top surface partially covered by the second top heat layer; and wherein
each of the top surfaces of the first power device chip and the second power device chip has a short edge and a long edge, the first connecting pillar is placed next to the long edge of the top surface of the first power device chip, and the second connecting pillar is placed next to the long edge of the top surface of the second power device chip.

18. The power module of claim 11, wherein:
each of the first top heat layer and the second top heat layer has a surface exposed at the first surface of the device substrate, and each of the first connecting pillar and the second connecting pillar has an end exposed at the first surface of the device substrate; and wherein
the first end of the first winding is physically attached to the surface of the first top heat layer and the end of the first connecting pillar by soldering or via a conductive adhesive, and the first end of the second winding is physically attached to the surface of the second top heat layer and the end of the second connecting pillar by soldering or via a conductive adhesive.

19. A power module, comprising:
an inductor assembly having a first surface and a second surface opposite to the first surface of the inductor assembly, wherein the inductor assembly comprises a magnetic core, a first winding and a second winding at least partially embedded within the magnetic core, each of the first winding and the second winding having a first end and a second end exposed at the second surface of the inductor assembly; and
a device substrate having a first surface and a second surface opposite to the first surface of the device substrate, the device substrate comprising:
a first power device chip and a second power device chip at least partially embedded within the device substrate;
a first top heat layer at least partially covering the first power device chip; and
a second top heat layer at least partially covering the second power device chip; wherein
the first end of the first winding is electrically connected to the first top heat layer, and the first end of the second winding is electrically connected to the second top heat layer.

20. The power module of claim 19, further comprising:
a bottom substrate having a first surface and a second surface opposite to the first surface of the bottom substrate, wherein the second surface of the bottom substrate comprises a first output voltage pad area and a second output voltage pad area; wherein
the first output voltage pad area has at least one pad electrically connected to the second end of the first winding, and the second output voltage pad area has at least one pad electrically connected to the second end of the second winding; and wherein
the device substrate is arranged on the bottom substrate with the second surface of the device substrate facing the first surface of the bottom substrate, and the inductor assembly is arranged on the device substrate with the second surface of the inductor assembly facing the first surface of the device substrate.

21. The power module of claim 19, wherein the inductor assembly further comprising:
a first heat sink layer and a second heat sink layer wrapping at least partial of the inductor assembly; wherein
the first heat sink layer is electrically connected to the first top heat layer, and the second heat sink layer is electrically connected to the second top heat layer.

22. The power module of claim 21, wherein the first heat sink layer has a portion physically attached to the surface of the first top heat layer by soldering or via a conductive adhesive, and the second heat sink layer has a portion physically attached to the surface of the second top heat layer by soldering or via a conductive adhesive.

23. The power module of claim 21, wherein:
the first heat sink layer has a first portion covering at least partial of the second surface of the inductor assembly and a second portion covering at least partial of a third surface of the inductor assembly, wherein the third surface of the inductor assembly is vertical to the first surface and the second surface of the inductor assembly; and wherein
the second heat sink layer has a first portion covering at least partial of the second surface of the inductor assembly and a second portion covering at least partial of a fourth surface of the inductor assembly, wherein the fourth surface of the inductor assembly is vertical to the first surface and the second surface of the inductor assembly and opposite to the third surface of the inductor assembly.

24. The power module of claim 19, wherein:
each of the first power device chip and the second power device chip has a first switch, a second switch and a switching pin electrically connected to a common node of the first switch and the second switch; and wherein
the first top heat layer is electrically coupled to the switching pin of the first power device chip, and the second top heat layer is electrically coupled to the switching pin of the second power device chip.

25. The power module of claim 24, wherein:
the device substrate further comprises a first connecting pillar and a second connecting pillar, wherein the first connecting pillar is electrically connected to the switching pin of the first power device chip, and the second connecting pillar is electrically connected to the switching pin of the second power device chip; and wherein
the first heat sink layer is electrically connected to the first connecting pillar, and the second heat sink layer is electrically connected to the second connecting pillar.

26. The power module of claim 24, wherein:
the device substrate further comprises a first connecting pillar and a second connecting pillar, wherein the first connecting pillar is electrically connected to the switching pin of the first power device chip and the first end of the first winding, and the second connecting pillar is electrically connected to the switching pin of the second power device chip and the first end of the second winding; and wherein
the first end of the first winding is electrically connected to the first connecting pillar, and the first end of the second winding is electrically connected to the second connecting pillar.

27. The power module of claim 26, wherein each of the first and second windings has a portion having a top surface exposed at the first surface of the inductor assembly.

28. The power module of claim 24, wherein each of the first power device chip and the second power device chip further comprises:
a driver;
an input pin;
a ground pin; and
a driving pin; wherein
the first switch has a first terminal coupled to the input pin, a second terminal coupled to the switching pin, and a control terminal configured to receive a first driving signal, and the second switch has a first terminal coupled to the switching pin, a second terminal coupled to the ground pin, and a control terminal configured to receive a second driving signal; and wherein
the driver is coupled to the driving pin to receive a phase control signal, and to provide the first driving signal and the second driving signal based on the phase control signal.
